(19) United States
(12) Patent Application Publication
(10) Pub. No.: US 2017/0250351 A1
(43) Pub. Date: Aug. 31, 2017

(54) MATERIAL FOR ORGANIC ELECTROLUMINESCENT DISPLAY DEVICE AND ORGANIC ELECTROLUMINESCENT DISPLAY DEVICE

(71) Applicant: Japan Display Inc., Tokyo (JP)

(72) Inventor: Jun TAKAGI, Tokyo (JP)

(21) Appl. No.: 15/430,919

(22) Filed: Feb. 13, 2017

(30) Foreign Application Priority Data
Feb. 25, 2016 (JP) 2016-034871

(51) Int. Cl. H01L 51/00; C09K 11/06; C09K 11/02

(52) U.S. Cl. CPC H01L 51/0072; C09K 11/025; C09K 11/06; H01L 51/0071; H01L 51/0067; H01L 51/006; H01L 51/0073; H01L 51/0055; H01L 51/5012

(57) ABSTRACT

A material for organic electroluminescent display device includes a luminescent dopant part and an assist dopant part. The luminescent dopant part may have an energy of 2.6 eV or higher to 3.0 eV or lower in an excited singlet state S₁ level. The assist dopant part may have an energy of 2.4 eV or higher to 3.0 eV or lower in the excited singlet state S₁ level. An energy gap ΔE_{ST} between the excited singlet state S₁ and an excited triplet state T₁ may be 0 eV or larger to 2.0 eV or smaller.

### CROSS REFERENCE TO RELATED APPLICATIONS

This application is based upon and claims the benefit of priority from the prior Japanese Patent Application No. 2016-034871, filed on Feb. 25, 2016, the entire contents of which are incorporated herein by reference.

### FIELD

The present invention relates to materials for organic electroluminescent display devices and organic electroluminescent display devices. In particular, the present invention relates to a material for organic electroluminescent display device and an organic electroluminescent display device with improved efficiency of energy transfer of a dopant in a luminescent layer.

### BACKGROUND

An organic electroluminescent element (hereinafter also referred to as “organic EL element”) has a structure in which a thin film containing an organic electroluminescent material (hereinafter also referred to as “organic EL material”) is sandwiched between two electrodes. The organic EL element contains a luminescent dopant constituted by fluorescent molecules that emit light when the energy of singlet exciters generated by recombination of holes and electrons in host molecules of the luminescent layer is transferred to the fluorescent molecules. Since the organic EL element has a luminescence intensity that can be controlled according to the applied voltage or the amount of current flowing through the element, a display device is under development which includes a display screen constituted by pixels formed by utilizing such characteristics of the organic EL element.

A display device including an organic EL element allows an image to be displayed by individually controlling the emission of light from each separate pixel. This eliminates the need for a backlight that is needed by a transmissive liquid crystal display device, allowing a reduction in thickness of the display device. Meanwhile, whereas singlet exciters account for 25% of exciters that are generated by recombination of holes and electrons in the luminescent layer, triplet exciters account for the remaining 75%. This results in thermal inactivation, making the luminescent element not high in efficiency.

A technique has recently been reported in which an assist dopant that allows the energy of singlet exciters to be transferred to fluorescent molecules is doped into the luminescent layer together with a luminescent dopant by converting triplet exciters into singlet exciters (Japanese Patent Laid-Open No. 2010-226055). Since it is substantially possible, in theory, to convert triplet exciters into singlet exciters with an assist dopant, a highly-efficient organic electroluminescent display device is expected to be achieved.

### SUMMARY

An embodiment of the present invention provides a material for organic electroluminescent display device including a luminescent dopant part and an assist dopant part.

An embodiment of the present invention provides an organic electroluminescent display device including a luminescent layer containing a material and a host material, the material including a luminescent dopant part and an assist dopant part.

### BRIEF DESCRIPTION OF THE DRAWINGS

FIG. 1A is a plan view for explaining a producing method of a flexible display device according to an embodiment of the present invention;

FIG. 1B is a sectional view for explaining a producing method of a flexible display device according to an embodiment of the present invention;

FIG. 2 is a sectional view showing the arrangement of an organic EL element 122 in a pixel unit 106 according to an embodiment of the present invention; and

FIG. 3 is a sectional view showing the arrangement of a pixel 120 in a pixel unit 106 according to an embodiment of the present invention.

### DESCRIPTION OF EMBODIMENTS

Embodiments of the present invention will be described below with reference to the accompanying drawings and the like. Note, however, that the present invention can be carried out in many different modes and should not be interpreted by only the written contents of embodiments exemplified below. In addition, for the sake of clearer explanation, the drawings sometimes show each portion more schematically than in actual modes in terms of width, thickness, shape, and the like. However, each drawing shows merely an example and should not limit the interpretation of the present invention. Furthermore, in this specification and the drawings, the same reference numerals denote the same elements as those described with reference to preceding drawings, and a detailed description will be appropriately omitted.

In this specification, a case in which a given member or region is located “on (or under)” another member or region includes not only a case in which a given member or region is located immediately above (or immediately below) another member or region but also a case in which a given member or region is located above (or below) another member of region, unless otherwise specified. That is, this case also includes a case in which another constituent element is located above (or below) another member or region so as to be included between a given member or region and another member or region.

Although it is substantially possible, in theory, to convert triplet exciters into singlet exciters with an assist dopant, an organic electroluminescent display device cannot be made higher in efficiency without sufficient efficiency in the transfer of energy to a luminescent dopant.

In view of such a problem, the present invention provides a material for organic electroluminescent display device and an organic electroluminescent display device with improved efficiency of energy transfer of a dopant in a luminescent layer.

A material for organic electroluminescent display device according to the present invention includes a luminescent dopant part and an assist dopant part. In an embodiment, the material for organic electroluminescent display device according to the present invention is a compound in which the luminescent dopant part and the assist dopant part bind with each other via a single bond or a linking group.

Conventionally, in a case where a luminescent dopant and an assist dopant are used in a luminescent layer, molecules have been in a state of random dispersion in the luminescent layer, as the luminescent layer has been formed by three-source vapor deposition of the luminescent dopant, the assist dopant, and a host material. For this reason, there are variations in the distances between molecules of the luminescent dopant and the assist dopant, and whereas there is a high probability of occurrence of energy transfer between molecules that are at a short distance from each other, there occurs no energy transfer between molecules that are at a long distance from each other. Such a mechanism of energy transfer is called the “Forster type”, whose velocity constant is proportional to the sixth power of the distance between two molecules. Therefore, in a state random dispersion of two or more types of dopant in the host material, the energy transfer does not proceed smoothly between a large number of molecules.

Meanwhile, since the material for organic electroluminescent display device according to the present invention is a compound in which the luminescent dopant part and the assist dopant part bind with each other via a single bond or a linking group, the luminescent dopant part and the assist dopant part are always present at a predetermined distance from each other, so that there is a very high probability of occurrence of energy transfer from the assist dopant part to the luminescent dopant part and high light emission efficiency can be achieved.

In an embodiment of the material for organic electroluminescent display device according to the present invention, the luminescent dopant part has an energy of 2.6 eV or higher to 3.0 eV or lower in an excited singlet state S₁ level, the assist dopant part has an energy of 2.4 eV or higher to 3.0 eV or lower in the excited singlet state S₁ level, and an energy gap ΔE_{ST} between the excited singlet state S₁ and an excited triplet state T₁ is 0 eV or larger to 2.0 eV or smaller.

Since the luminescent dopant part and the assist dopant part have such energy level characteristics, energy is converted with high efficiency from the excited singlet state S₁ to the excited triplet state T₁ in the assist dopant part, and the transfer of energy from the assist dopant part to the luminescent dopant part can be achieved with very high efficiency.

In an embodiment, the material for organic electroluminescent display device according to the present invention is selected from a group consisting of compounds represented by formulae (1) to (6):

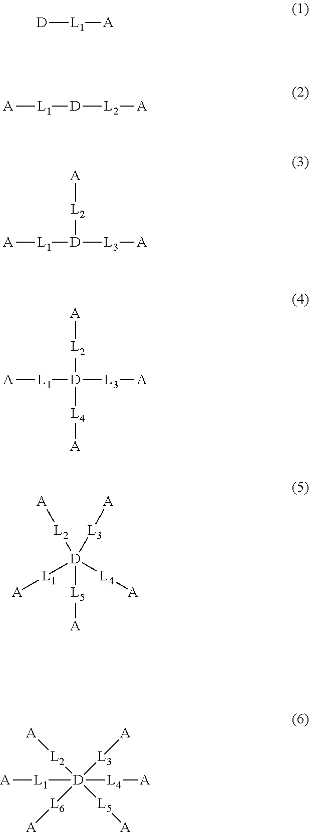

As described above, it is preferable that the material for organic electroluminescent display device according to the present invention be a compound containing the assist dopant part at a ratio of combination of 1 to 6 to the luminescent dopant part.

Note here that D represents the luminescent dopant part and A represents the assist dopant part. L₁ to L₆ are each selected from a group consisting of a single bond, a nitrogen atom, an oxygen atom, sulfur, a substituted or unsubstituted divalent hydrocarbon group, a substituted or unsubstituted divalent hydrocarbon group including one or more double bonds, a substituted or unsubstituted divalent hydrocarbon group including one or more triple bonds, and a substituted or unsubstituted divalent hydrocarbon group including one or more double bonds and triple bonds.

Examples of the substituted or unsubstituted divalent hydrocarbon group are single-bond divalent groups, particularly a substituted or unsubstituted alkylene group and a substituted or unsubstituted cycloalkylene group. Examples of the substituted or unsubstituted divalent hydrocarbon group including one or more double bonds are a substituted or unsubstituted alkenylene group, a substituted or unsubstituted phenylene group, and a heteroarylene group. Further, the substituted or unsubstituted divalent hydrocarbon group including one or more triple bonds is a substituted or unsubstituted alkynylene group.

Further, in the material for organic electroluminescent display device according to the present invention, it is preferable that the assist dopant part be selected from, but not be limited to, a group consisting of compounds represented by formulae (7) to (24):

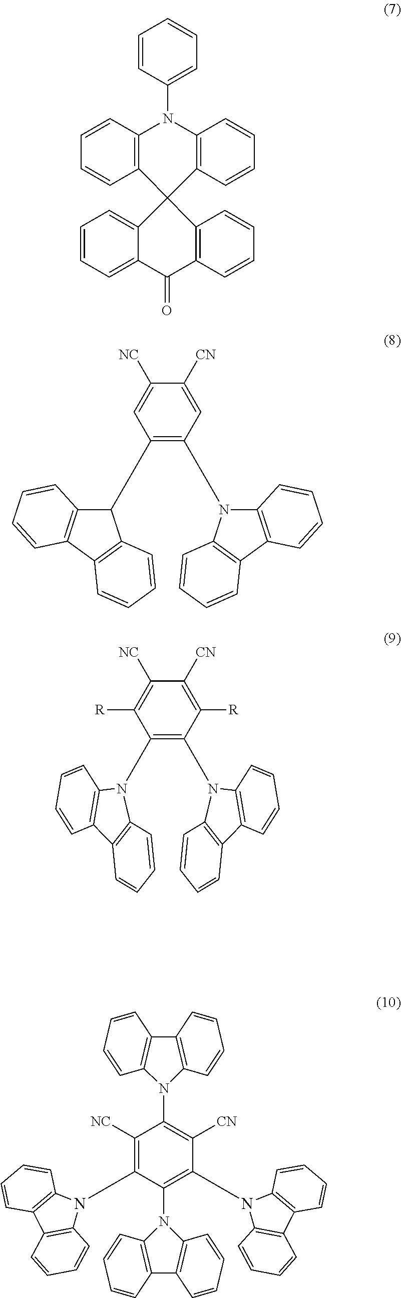

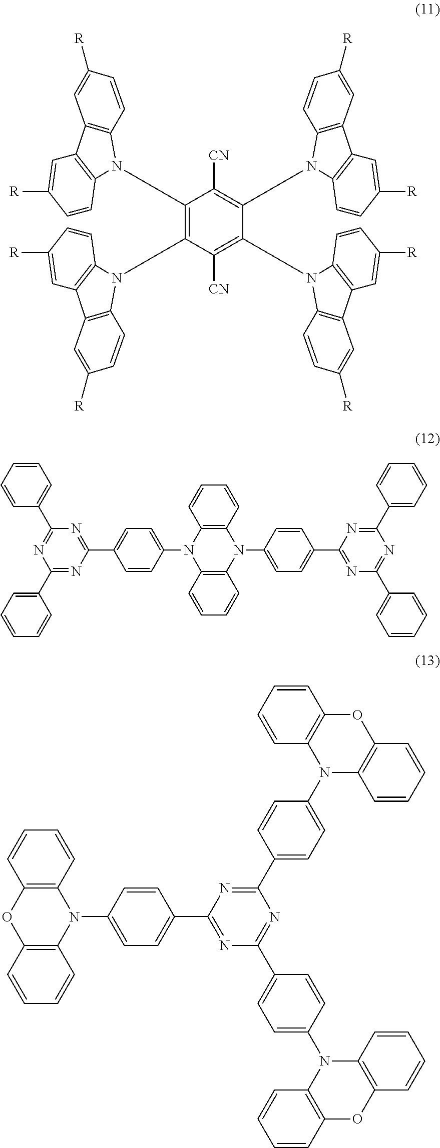

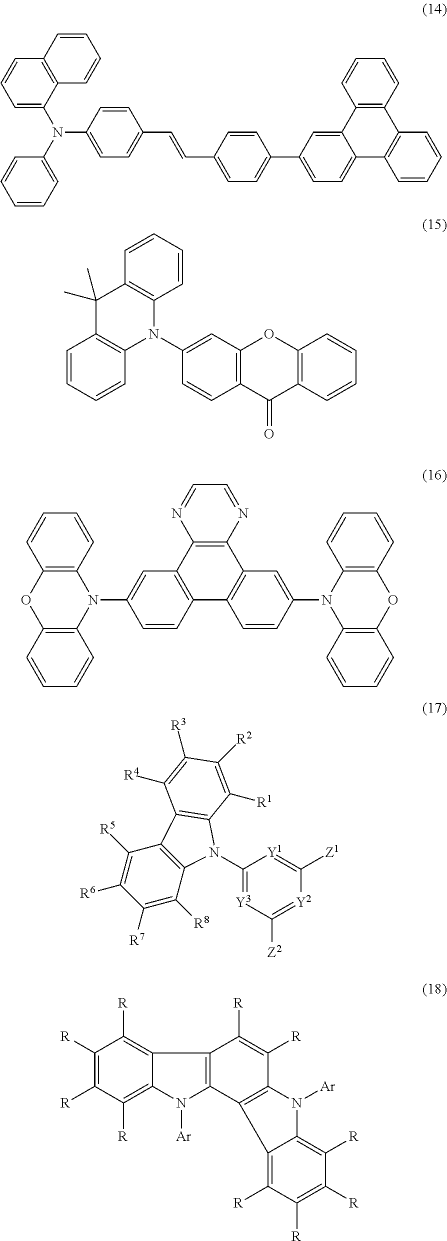

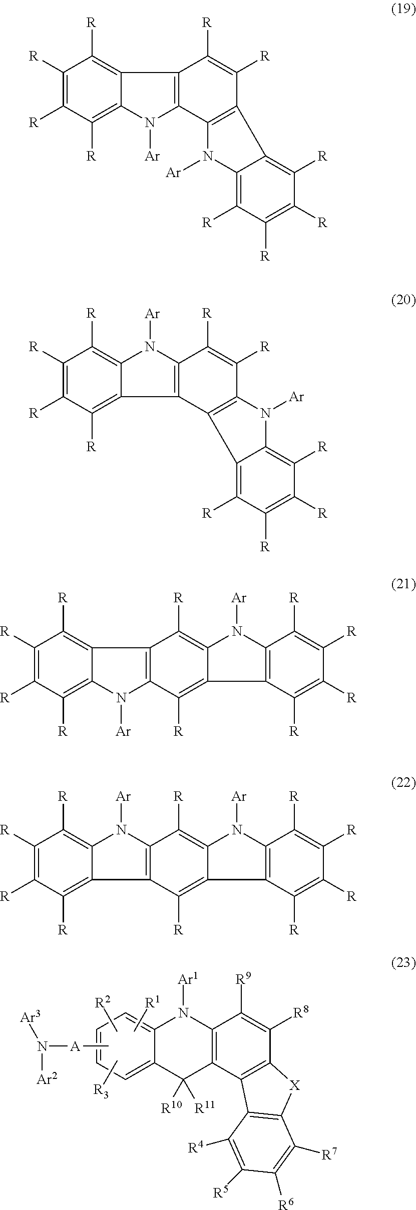

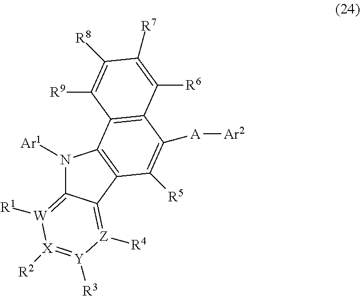

Note here that, in formula (9), R represents a hydrogen atom or a carbazolyl group; in formula (11), R represents a hydrogen atom, a methyl group, or a phenyl group; and in formula (17), R represents a hydrogen atom, a methyl group, or a phenyl group, Y² and Y³ represent nitrogen atoms and Y¹ represents a methine group or all of Y¹, Y², and Y³ represent nitrogen atoms, Z¹ and Z² independently represent a hydrogen atom or a substituent, Z² represents a hydrogen atom, a substituted or unsubstituted alkyl group, or a substituted or unsubstituted aryl group when Y² and Y³ are nitrogen atoms and Y¹ is a methine group, R¹ to R⁸ independently represent a hydrogen atom or a substituent, at least one of R¹ to R⁸ represents a substituted or unsubstituted diarylamino group or a substituted or unsubstituted carbazolyl group, and at least one of R¹ to R⁸ represents a substituted or unsubstituted diarylamino group or a substituted or unsubstituted 9-carbazolyl group and includes at least two carbazole structures when all of Y¹, Y², and Y³ are nitrogen atoms.

In formula (17), Z¹ and Z² independently represent a hydrogen atom or a substituent. Preferred examples of substituents that Z¹ and Z² may assume are a C1-C20 alkyl group, a C1-C20 alkoxy group, a C1-C20 alkylthio group, a C1-C20 alkyl-substituted amino group, a C2-C20 acyl group, a C6-C40 aryl group, a C3-C40 heteroaryl group, a C12-C40 diarylamino group, a C12-C40 substituted or unsubstituted carbazolyl group, a C2-C10 alkenyl group, a C2-C10 alkynyl group, a C2-C10 alkoxycarbonyl group, a C1-C10 alkylsulfonyl group, a C1-C10 haloalkyl group, an amide group, a C2-C10 alkylamide group, a C3-C20 trialkylsilyl group, a C4-C20 trialkylsilylalkyl group, a C5-C20 trialkylsilylalkenyl group, a C5-C20 trialkylsilylalkynyl group, a cyano group, a nitro group, a hydroxyl group, and the like, and these groups may be further substituted by substituents. More preferably, Z¹ and Z² are independently a hydrogen atom, a C1-020 substituted or unsubstituted alkyl group, a C6-C40 substituted or unsubstituted aryl group, a C3-C40 substituted or unsubstituted heteroaryl group, a C12-C40 substituted or unsubstituted diarylamino group, or a C12-C40 substituted or unsubstituted carbazolyl group. Even more preferably, Z¹ and Z² are independently a hydrogen atom, a C1-010 substituted or unsubstituted alkyl group, a C6-C15 substituted or unsubstituted aryl group, a C3-C12 substituted or unsubstituted heteroaryl group, or a C12-C24 substituted or unsubstituted 9-carbazolyl group. Still even more preferably, Z¹ is a C6-C15 substituted or unsubstituted aryl group, a C3-C12 substituted or unsubstituted heteroaryl group, or a C12-C24 substituted or unsubstituted 9-carbazolyl group. Still even more preferably, Z² is a hydrogen atom, a C1-010 substituted or unsubstituted alkyl group, a C6-C15 substituted or unsubstituted aryl group, or a C3-C12 substituted or unsubstituted heteroaryl group.

The alkyl group may be linear, branched, or cyclic. More preferably, the alkyl group is a C1-C6 alkyl group whose specific examples can be a methyl group, an ethyl group, a propyl group, a butyl group, a t-butyl group, a pentyl group, a hexyl group, and an isopropyl group. The aryl group may be a monocyclic or condensed aryl group whose specific examples can be a phenyl group and a naphthyl group. The heteroaryl group may be a monocyclic or condensed heteroaryl group whose specific examples can be a pyridyl group, a pyridazyl group, a pyrymidyl group, a triazyl group, a triazolyl group, and a benzotriazolyl group. These heteroaryl groups may be groups that bind via a hetero atom, but preferably, they are groups that bind via a carbon atom constituting a heteroaryl ring. In a case where the 9-carbazolyl group is substituted, it is preferable that the 9-carbazolyl group be substituted by the alkyl group, the aryl group, the heteroaryl group, the cyano group, the diarylamino group, or the carbazolyl group described above.

In formula (17), R¹ to R⁸ independently represent a hydrogen atom or a substituent. Preferred examples of substituents that R¹ to R⁸ may assume are a C1-C20 alkyl group, a C7-C20 aralkyl group, a C2-C20 alkenyl group, a C2-C20 alkynyl group, a C6-C30 aryl group, a C3-C30 heteroaryl group, a cyano group, a C2-C20 dialkylamino group, a C12-C30 diarylamino group, a C12-C30 carbazolyl group, a C12-C30 diaralkylamino group, an amino group, a nitro group, a C2-C20 acyl group, a C2-C20 alkoxycarbonyl group, a C1-C20 alkoxy group, a C1-C20 alkylsulfonyl group, a hydroxyl group, an amide group, a C1-C10 haloalkyl group, a C2-C10 alkylamide group, a C3-C20 trialkylsilyl group, a C4-C20 trialkylsilylalkyl group, a C5-C20 trialkylsilylalkenyl group, and a C5-C20 trialkylsilylalkynyl group, and these groups may be further substituted by substituents. More preferably, R¹ to R⁸ are independently a hydrogen atom, a C1-020 substituted or unsubstituted alkyl group, a substituted or unsubstituted aryl group having 6 to 30 ring-forming carbon atoms, a substituted or unsubstituted heteroaryl group having 3 to 30 ring-forming carbon atoms, a substituted or unsubstituted diarylamino group having 12 to 30 ring-forming carbon atoms, or a carbazolyl group having 12 to 30 ring-forming carbon atoms. Even more preferably, R¹ to R⁸ are independently a hydrogen atom, a C1-010 substituted or unsubstituted alkyl group, a substituted or unsubstituted aryl group having 6 to 15 ring-forming carbon atoms, a substituted or unsubstituted heteroaryl group having 3 to 12 ring-forming carbon atoms, a substituted or unsubstituted diphenylamino group having 12 to 24 ring-forming carbon atoms, or a carbazolyl group having 12 to 24 ring-forming carbon atoms.

In formula (17), at least one of R¹ to R⁸ represents a substituted or unsubstituted diarylamino group or a substituted or unsubstituted carbazolyl group. Specific examples of the carbazolyl group are a 9-carbazolyl group, a 1-carbazolyl group, a 2-carbazolyl group, a 3-carbazolyl group, and a 4-carbazolyl group, preferably a 9-carbazolyl group and a 3-carbazolyl group, more preferably a 9-carbazolyl group. When the diarylamino group or the carbazolyl group has a substituent, there is not particular limitation on the type of substituent, but preferred examples may be the preferred substituents that R¹ to R⁸ may assume. In formula (17), any of R¹ to R⁸ may be a substituted or unsubstituted diarylamino group or a substituted or unsubstituted carbazolyl group, but it is preferable that at least one of R³ and R⁶ be a substituted or unsubstituted diarylamino group or a substituted or unsubstituted carbazolyl group.

Further, the compound represented by formula (17) includes at least two carbazole structures in each molecule. Since formula (17) already contains one carbazole structure, it is necessary that at least one of R¹ to R⁸, Z¹, and Z² be a group including a carbazole structure. A preferable case is one where at least one of R¹ to R⁴, R⁵ to R⁸, and Z¹ is a group including a carbazole structure. A more preferable case is one where at least one of R³, R⁶, and Z¹ is a group including a carbazole structure. It is also preferable that any two of R³, R⁶, and Z¹ be groups each including a carbazole structure, and it is also preferable that all of R³, R⁶, and Z¹ be groups each including a carbazole structure.

It is more preferable that the compound represented by formula (17) include at least three carbazole structures in each molecule, and it is even more preferable that the compound represented by formula (17) include at least four carbazole structures in each molecule.

In formulae (18) to (22), each Ar independently represents an aromatic hydrocarbon group or an aromatic heterocyclic group and each R independently represents hydrogen or a monovalent substituent and includes a structure in which adjacent substituents are combined or are not combined to form a ring.

In formulae (18) to (22), preferably, Ar is an aromatic hydrocarbon group having 6 to 100 ring-forming carbon atoms or an aromatic heterocyclic group having 3 to 100 ring-forming carbon atoms, more preferably an aromatic hydrocarbon group having 5 to 50 ring-forming carbon atoms or an aromatic heterocyclic group having 3 to 50 ring-forming carbon atoms. Even more preferably, Ar is an aromatic hydrocarbon group having 6 to 50 ring-forming carbon atoms or a ring-forming aromatic heterocyclic group having 3 to 50 ring-forming carbon atoms. In a case where these aromatic hydrocarbon groups or aromatic heterocyclic groups have one or more substituents, the calculation of the carbon number includes the carbon numbers of those substituents.

Preferred examples of the aromatic hydrocarbon group or the aromatic heterocyclic group include a group formed by removing one hydrogen atom from benzene, pentalene, indene, naphthalene, azulene, heptalene, octalene, indacene, acenaphthylene, phenalene, phenanthrene, anthracene, trindene, fluoranthene, acephenanthrylene, aceanthrylene, triphenylene, pyrene, chrysene, tetraphene, tetracene, pleiadene, picene, perylene, pentaphene, pentacene, tetraphenylene, cholanthrylene, helicene, hexaphene, rubicene, coronene, trinaphthylene, heptaphene, pyranthrene, ovalene, corannulene, fulminene, anthanthrene, zethrene, terylene, naphthacenonaphthacene, truxene, furan, benzofuran, isobenzofuran, xanthene, oxathrene, dibenzofuran, peri-xanthenoxanthene, thiophene, thioxanthene, thianthrene, phenoxathiin, thionaphthene, isothianaphthene, thiophthene, thiophanthrene, dibenzothiophene, pyrrole, pyrazole, tellurazole, selenazole, thiazole, isothiazole, oxazole, furazan, pyridine, pyrazine, pyrimidine, pyridazine, triazine, indolizine, indole, isoindole, indazole, purine, quinolizine, isoquinoline, carbazole, indolocarbazole, imidazole, naphthyridine, phthalazine, quinazoline, benzodiazepine, quinoxaline, cinnoline, quinoline, pteridine, phenanthridine, acridine, perimidine, phenanthroline, phenazine, carboline, phenotellurazine, phenoselenazines, phenothiazine, phenoxazine, anthyridine, thebenidine, quindoline, quinindoline, acrindoline, phthaloperine, triphenodiazine, triphenodioxazine, phenanthrazine, anthrazine, benzothiazole, benzimidazole, benzoxazole, benzisoxazole, benzisothiazole, or an aromatic compound in which a plurality of these aromatic rings are linked. More preferred examples of the aromatic hydrocarbon group or the aromatic heterocyclic group include a group formed by removing one hydrogen atom from benzene, naphthalene, anthracene, pyridine, pyrazine, pyrimidine, pyridazine, triazine, isoindole, indazole, purine, isoquinoline, imidazole, naphthyridine, phthalazine, quinazoline, benzodiazepine, quinoxaline, cinnoline, quinoline, pteridine, phenanthridine, acridine, perimidine, phenanthroline, phenazine, carboline, indole, carbazole, indolocarbazole, or an aromatic compound in which a plurality of these aromatic rings are linked. It should be noted that in the case of a group formed from an aromatic compound in which a plurality of aromatic rings are linked, the preferred number of aromatic rings that are linked is 2 to 10, more preferably 2 to 7, and the aromatic rings that are linked may be identical to or different from each other. In that case, the binding position of Ar that binds with N is not limited but may be a ring at the end or center of the linked aromatic rings. Further, in a case where Ar is a group formed by removing one hydrogen atom from an aromatic compound in which a plurality of these aromatic rings are linked, the group is included in aromatic hydrocarbon groups in a case where the first aromatic ring to bind with N in formulae (18) to (22) is an aromatic hydrocarbon ring, and the group is included in aromatic heterocyclic groups in a case where the first aromatic ring to bind with N is an aromatic heterocycle. The term “aromatic rings” here collectively means aromatic hydrocarbon rings and aromatic heterocycles.

A specific example of the group formed by linking a plurality of aromatic rings is a group formed by removing one hydrogen atom from biphenyl, terphenyl, bipyridine, bipyrimidine, bitriazine, terpyridine, bis(triazil)benzene, dicarbazolylbenzene, carbazolylbiphenyl, dicarbazolylbiphenyl, indolocarbazolyltriazine, phenylterphenyl, carbazolylterphenyl, binaphthalene, phenylpyridine, phenylcarbazole, diphenylcarbazole, diphenylpyridine, phenylpyrimidine, diphenylpyrimidine, phenyltriazine, diphenyltriazine, phenylnaphthalene, diphenylnaphthalene, indolocarbazolylbenzene, indolocarbazolylpyridine, indolocarbazolyltriazine, or the like.

The aromatic hydrocarbon group or the aromatic heterocyclic group may have a substituent, and the total number of substituents is 1 to 10, preferably 1 to 6, more preferably 1 to 4. It should be noted the group formed from an aromatic compound in which a plurality of aromatic rings are linked can similarly have a substituent. Preferred examples of such substituents are a C1-C20 alkyl group, a C1-C20 alkoxy group, a C1-C20 alkylthio group, a C1-C20 alkyl-substituted amino group, a C2-C20 acyl group, a diarylamino group having 12 to 24 ring-forming carbon atoms, a C2-C10 alkenyl group, a C2-C10 alkynyl group, a C2-C10 alkoxycarbonyl group, a C1-C10 alkylsulfonyl group, a C1-C10 haloalkyl group, an amide group, a C2-C10 alkylamide group, a C3-C20 trialkylsilyl group, a C4-C20 trialkylsilylalkyl group, a C5-C20 trialkylsilylalkenyl group, a C5-C20 trialkylsilylalkynyl group, a cyano group, a nitro group, a hydroxyl group, and the like. More preferred examples are a methyl group, an ethyl group, an n-propyl group, an i-propyl group, an n-butyl group, a t-butyl group, a methoxy group, an ethoxy group, an n-propoxy group, an i-propoxy group, and a diphenylamino group. In a case where the aromatic hydrocarbon group or the aromatic heterocyclic group has two or more substituents, the two or more substituents may be identical to or different from each other.

It is preferable that at least one of Ar's in formulae (18) to (22) be an aromatic heterocyclic group, and it is more preferable that at least one of Ar's in formulae (18) to (22) be a group represented by formula (25):

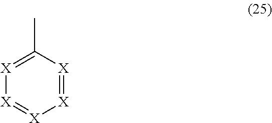

wherein each X independently represents N, C—H, or C—Ar₁ and at least one of X's is N. Each Ar₁ independently represents an aromatic hydrocarbon group or an aromatic heterocyclic group. The preferred number of N's is 1 to 3, more preferably 2 to 3, even more preferably 3. In a case where X is C—Ar₁, Ar₁ and a ring including X may share one side to form a condensed ring. Preferred specific examples of Ar₁ are the same as those of the aromatic hydrocarbon group or the aromatic heterocyclic group denoted by Ar. Further, the same applies to preferred substituents.

A specific example of the group represented by formula (25) is a group formed from pyridine, pyrazine, pyrimidine, pyridazine, or triazine. A specific example of a case where formula (25) forms a condensed ring in which Ar₁ and a ring including X share one side is a group formed by removing one hydrogen atom from indolizine, purine, quinolizine, isoquinoline, naphthyridine, phthalazine, quinazoline, quinoxaline, cinnoline, quinoline, pteridine, phenanthridine, acridine, perimidine, phenanthroline, phenazine, carboline, anthyridine, thebenidine, quindoline, quinindoline, acrindoline, or phthaloperine, preferably a group formed by removing one hydrogen atom from pyridine, pyrazine, pyrimidine, pyridazine, triazine, purine, quinolizine, naphthyridine, phthalazine, quinazoline, quinoxaline, cinnoline, pteridine, or anthyridine.

In formulae (18) to (22), each R independently represents hydrogen or a monovalent substituent. An example of R is hydrogen, a C1-C20 alkyl group, a C7-C20 aralkyl group, a C2-C20 alkenyl group, a C2-C20 alkynyl group, a cyano group, a C2-C20 dialkylamino group, a diarylamino group having 12 to 20 ring-forming carbon atoms, a C12-C20 diaralkylamino group, an amino group, a nitro group, a C2-C20 acyl group, a C2-C20 alkoxycarbonyl group, a C1-C20 alkoxy group, a C1-C20 alkylsulfonyl group, a hydroxyl group, an amide group, a substituted or unsubstituted aromatic hydrocarbon group having 6 to 30 ring-forming carbon atoms or a substituted or unsubstituted aromatic heterocyclic group having 3 to 30 ring-forming carbon atoms, a C1-C10 haloalkyl group, a C2-C10 alkylamide group, a C3-C20 trialkylsilyl group, a C4-C20 trialkylsilylalkyl group, a C5-C20 trialkylsilylalkenyl group, or a C5-C20 trialkylsilylalkynyl group. A preferred example is hydrogen, a C1-C10 alkyl group, a C1-C10 alkoxy group, a C1-C10 alkylthio group, a C1-C10 alkylamino group, a C2-C10 acyl group, a C7-C20 aralkyl group, a substituted or unsubstituted aromatic hydrocarbon group having 6 to 30 ring-forming carbon atoms or a substituted or unsubstituted aromatic six-membered heterocyclic group having 3 to 30 ring-forming carbon atoms, or the like. More preferably, R is hydrogen, a C1-C3 alkyl group, a C1-C3 alkoxy group, a C2-C4 acyl group, a phenyl group, or a pyridyl group.

In formula (23), X represents an oxygen atom or a sulfur atom, and R¹ to R⁹ each represent a hydrogen atom, a deuterium atom, a fluorine atom, a chlorine atom, a cyano group, a nitro group, a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, or an aryloxy group and have structures that form or do not form a ring by binding with each other via a single bond, a methylene group, an oxygen atom, or a sulfur atom. R¹⁰ and R¹¹ each represent a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, or an aryloxy group and have structures that form or do not form a ring by binding with each other via a single bond, a methylene group, an oxygen atom, or a sulfur atom. Ar¹, Ar², and Ar³ each represent an aromatic hydrocarbon group, an aromatic heterocyclic group, or a condensed polycyclic aromatic group. Ar² and Ar³ have structures that form or do not form a ring by binding with each other via a single bond, a methylene group, an oxygen atom, or a sulfur atom. A represents either a divalent group of an aromatic hydrocarbon, an aromatic heterocycle, or a condensed polycyclic aromatic compound or a single bond. In a case where A is a divalent group of an aromatic hydrocarbon, an aromatic heterocycle, or a condensed polycyclic aromatic compound, A and Ar² have structures that form or do not form a ring by binding with each other via a single bond, a methylene group, an oxygen atom, or a sulfur atom.

Of the compounds of the present invention represented by formula (23) above, a preferred compound is one in which, in a benzene ring with which A binds, R¹, R², R³, and A bind at positions represented by formula (26):

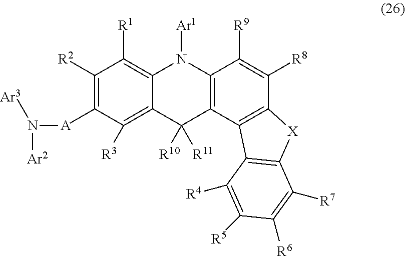

X represents an oxygen atom or a sulfur atom. When X is a sulfur atom, the compound of the present invention has a benzothienoacridone ring structure. Further, when X is an oxygen atom, the compound of the present invention has a benzofuroacridone ring structure.

R¹ to R⁹ may be identical to or different from each other and each represent a hydrogen atom, a deuterium atom, a fluorine atom, a chlorine atom, a cyano group, a nitro group, a C1-C6 alkyl group, a C5-C10 cycloalkyl group, a C2-C6 alkenyl group, a C1-C6 alkyloxy group, a cycloalkyloxy group having 5 to 10 ring-forming carbon atoms, an aromatic hydrocarbon group, an aromatic heterocyclic group, a condensed polycyclic aromatic group, or an aryloxy group. These groups may form a ring by binding with each other via a single bond, a methylene group that may have a substituent, an oxygen atom, or a sulfur atom.

Examples of the C1-C6 alkyl group, the cycloalkyl group having 5 to 10 ring-forming carbon atoms, or the C2-C6 alkenyl group represented by R¹ to R⁹ can be a methyl group, an ethyl group, an n-propyl group, an isopropyl group, an n-butyl group, an isobutyl group, a tert-butyl group, an n-pentyl group, an isopentyl group, a neopentyl group, an n-hexyl group, a cyclopentyl group, a cyclohexyl group, a 1-adamantyl group, a 2-adamantyl group, a vinyl group, an allyl group, an isopropenyl group, a 2-butenyl group, and the like. The C1-C6 alkyl group and the C2-C6 alkenyl group represented by R¹ to R⁹ may be linear or branched.

The C1-C6 alkyl group, the cycloalkyl group having 5 to 10 ring-forming carbon atoms, or the C2-C6 alkenyl group represented by R¹ to R⁹ may have a substituent. Examples of such substituents can be a deuterium atom, a cyano group, a nitro group, halogen atoms such as a fluorine atom, a chlorine atom, a bromine atom, and a iodine atom, linear or branched C1-C6 alkyloxy groups such as a methyloxy group, an ethyloxy group, and a propyloxy group, alkenyl groups such as an allyl group, aryloxy groups such as a phenyloxy group and a tolyloxy group, arylalkyloxy groups such as a benzyloxy group and a phenethyloxy group, aromatic hydrocarbon groups or condensed polycyclic aromatic groups such as a phenyl group, a biphenylyl group, a terphenylyl group, a naphthyl group, an anthracenyl group, a phenanthryl group, a fluorenyl group, an indenyl group, a pyrenyl group, a perylenyl group, a fluoranthenyl group, and a triphenylenyl group, and aromatic heterocyclic groups such as a pyridyl group, a thienyl group, a furyl group, a pyrrolyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzimidazolyl group, a pyrazolyl group, a dibenzofuranyl group, a dibenzothienyl group, and a carbolinyl group. These substituents may have further substituents. Examples of such further substituents can be the same as those substituents named above. Further, these substituents may form a ring by binding with each other via a single bond, a methylene group that may have a substituent, an oxygen atom, or a sulfur atom.

Examples of the C1-C6 alkyloxy group or the C5-C10 cycloalkyloxy group represented by R¹ to R⁹ can be a methyloxy group, an ethyloxy group, an n-propyloxy group, an isopropyloxy group, an n-butyloxy group, a tert-butyloxy group, an n-pentyloxy group, an n-hexyloxy group, a cyclopentyloxy group, a cyclohexyloxy group, a cycloheptyloxy group, a cyclooctyloxy group, a 1-adamantyloxy group, a 2-adamantyloxy group, and the like. The C1-C6 alkyloxy group represented by R¹ to R⁹ may be linear or branched.

The C1-C6 alkyloxy group or the C5-C10 cycloalkyloxy group represented by R¹ to R⁹ may have a substituent. Examples of such substituents can be the same as those substituents which the C1-C6 alkyl group, the cycloalkyl group having 5 to 10 ring-forming carbon atoms, or the C2-C6 alkenyl group represented by R¹ to R⁹ may have. Further, these substituents may have further substituents. Example of such further substituents can be the same as those substituents which the C1-C6 alkyl group, the cycloalkyl group having 5 to 10 ring-forming carbon atoms, or the C2-C6 alkenyl group represented by R¹ to R⁹ may have. The substituents exemplified above may form a ring by binding with each other via a single bond, a methylene group that may have a substituent, an oxygen atom, or a sulfur atom.

Examples of the aromatic hydrocarbon group, the aromatic heterocyclic group, or the condensed polycyclic aromatic group represented by R¹ to R⁹ can be a phenyl group, a biphenylyl group, a terphenylyl group, a naphthyl group, an anthryl group, a phenanthryl group, a fluorenyl group, an indenyl group, a pyrenyl group, a perylenyl group, a fluoranthenyl group, a triphenylenyl group, a pyridyl group, a furyl group, a pyrrolyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzimidazolyl group, a pyrazolyl group, a dibenzofuranyl group, a dibenzothienyl group, a carbolinyl group, and the like. It is preferable that the aromatic heterocyclic group represented by R¹ to R⁹ be a sulfur-containing aromatic heterocyclic group such as a thienyl group, a benzothienyl group, a benzothiazolyl group, or a dibenzothienyl group.

The aromatic hydrocarbon group, the aromatic heterocyclic group, or the condensed polycyclic aromatic group represented by R¹ to R⁹ may have a substituent. Examples of such substituents can be a deuterium atom, a trifluoromethyl group, a cyano group, a nitro group, halogen atoms such as a fluorine atom, a chlorine atom, a bromine atom, and a iodine atom, linear or branched C1-C6 alkyl groups such as a methyl group, an ethyl group, an n-propyl group, an isopropyl group, an n-butyl group, an isobutyl group, a tert-butyl group, an n-pentyl group, an isopentyl group, a neopentyl group, and an n-hexyl group, linear or branched C1-C6 alkyloxy groups such as a methyloxy group, an ethyloxy group, and a propyloxy group, alkenyl groups such as an allyl group, aralkyl groups such as a benzyl group, a naphthylmethyl group, and a phenethyl group, aryloxy groups such as a phenyloxy group and a tolyloxy group, arylalkyloxy groups such as a benzyloxy group and a phenethyloxy group, aromatic hydrocarbon groups or condensed polycyclic aromatic groups such as a phenyl group, a biphenylyl group, a terphenylyl group, a naphthyl group, an anthracenyl group, a phenanthryl group, a fluorenyl group, an indenyl group, a pyrenyl group, a perylenyl group, a fluoranthenyl group, and a triphenylenyl group, aromatic heterocyclic groups such as a pyridyl group, a thienyl group, a furyl group, a pyrrolyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzimidazolyl group, a pyrazolyl group, a dibenzofuranyl group, a dibenzothienyl group, and a carbolinyl group, arylvinyl groups such as a styryl group and a naphthylvinyl group, acyl groups such as an acetyl group and a benzoyl group, dialkylamino groups such as a dimethylamino group and a diethylamino group, disubstituted amino groups substituted by an aromatic hydrocarbon group or a condensed polycyclic aromatic group, such as a diphenylamino group and a dinaphthylamino group, diaralkylamino groups such as a dibenzylamino group and a diphenethylamino group, a disubstituted amino group substituted by an aromatic heterocyclic group, such as a dipyridylamino group and a dithienylamino group, dialkenyl groups such as a disubstituted amino group substituted by a substituent selected from a diallylamino group, an alkyl group, an aromatic hydrocarbon group, a condensed polycyclic aromatic group, an aralkyl group, an aromatic heterocyclic group, and an alkenyl group, and the like. These substituents may have further substituents. Examples of such further substituents can be the same as those of the substituent that the aromatic hydrocarbon group or the like represented by R¹ to R⁹ has. Further, these substituents may form a ring by binding with each other via a single bond, a methylene group that may have a substituent, an oxygen atom, or a sulfur atom.

Examples of the aryloxy group represented by R¹ to R⁹ can be a phenyloxy group, a biphenylyloxy group, a terphenylyloxy group, a naphthyloxy group, an anthryloxy group, a phenanthryloxy group, a fluorenyloxy group, an indenyloxy group, a pyrenyloxy group, a perylenyloxy group, and the like.

The aryloxy group represented by R¹ to R⁹ may have a substituent. Examples of such substituents can be the same as those substituents which the aromatic hydrocarbon group, the aromatic heterocyclic group, or the condensed polycyclic aromatic group represented by R¹ to R⁹ may have. These substituents may have further substituents. Examples of such further substituents can be the same as those substituents which the aromatic hydrocarbon group, the aromatic heterocyclic group, or the condensed polycyclic aromatic group represented by R¹ to R⁹ may have. These substituents may form a ring by binding with each other via a single bond, a methylene group that may have a substituent, an oxygen atom, or a sulfur atom.

R¹⁰ and R¹¹ may be identical to or different from each other and each represent a C1-C6 alkyl group, a cycloalkyl group having 5 to 10 ring-forming carbon atoms, a C2-C6 alkenyl group, a C1-C6 alkyloxy group, a cycloalkyloxy group having 5 to 10 ring-forming carbon atoms, an aromatic hydrocarbon group, an aromatic heterocyclic group, a condensed polycyclic aromatic group, or an aryloxy group. These groups may form a ring by binding with each other via a single bond, a methylene group that may have a substituent, an oxygen atom, or a sulfur atom.

Examples of the C1-C6 alkyl group, the cycloalkyl group having 5 to 10 ring-forming carbon atoms, or the C2-C6 alkenyl group represented by R¹⁰ and R¹¹ can be the same as those of the C1-C6 alkyl group, the cycloalkyl group having 5 to 10 ring-forming carbon atoms, or the C2-C6 alkenyl group represented by R¹ to R⁹. As can be seen from the exemplified groups, the C1-C6 alkyl group or the C2-C6 alkenyl group represented by R¹⁰ and R¹¹ may be linear or branched.

The C1-C6 alkyl group, the cycloalkyl group having 5 to 10 ring-forming carbon atoms, or the C2-C6 alkenyl group represented by R¹⁰ and R¹¹ may have a substituent. Examples of such substituents can be the same as those substituents which the C1-C6 alkyl group, the cycloalkyl group having 5 to 10 ring-forming carbon atoms, or the C2-C6 alkenyl group represented by R¹ to R⁹ may have. These substituents may have further substituents. Examples of such further substituents can be the same as those substituents which the C1-C6 alkyl group, the cycloalkyl group having 5 to 10 ring-forming carbon atoms, or the C2-C6 alkenyl group represented by R¹ to R⁹ may have. These substituents may form a ring by binding with each other via a single bond, a methylene group that may have a substituent, an oxygen atom, or a sulfur atom.

Examples of the C1-C6 alkyloxy group or the C5-C10 cycloalkyloxy group represented by R¹⁰ and R¹¹ can be the same as those of the C1-C6 alkyloxy group or the C5-C10 cycloalkyloxy group represented by R¹ to R⁹. The C1-C6 alkyloxy group may be linear or branched. The C1-C6 alkyloxy group or the cycloalkyloxy group having 5 to 10 ring-forming carbon atoms represented by R¹⁰ and R¹¹ may have a substituent. Examples of such substituents can be the same as those substituents which the C1-C6 alkyl group, the cycloalkyl group having 5 to 10 ring-forming carbon atoms, or the C2-C6 alkenyl group represented by R¹ to R⁹ may have. Further, these substituents may have further substituents. Examples of such further substituents can be the same as those substituents which the C1-C6 alkyl group, the cycloalkyl group having 5 to 10 ring-forming carbon atoms, or the C2-C6 alkenyl group represented by R¹ to R⁹ may have. The substituents exemplified above may form a ring by binding with each other via a single bond, a methylene group that may have a substituent, an oxygen atom, or a sulfur atom.

Examples of the aromatic hydrocarbon group, the aromatic heterocyclic group, or the condensed polycyclic aromatic group represented by R¹⁰ and R¹¹ can be the same as those of the aromatic hydrocarbon group, the aromatic heterocyclic group, or the condensed polycyclic aromatic group represented by R¹ to R⁹. It is preferable that the aromatic heterocyclic group represented by R¹⁰ and R¹¹ be a sulfur-containing aromatic heterocyclic group such as a thienyl group, a benzothienyl group, a benzothiazolyl group, or a dibenzothienyl group.

The aromatic hydrocarbon group, the aromatic heterocyclic group, or the condensed polycyclic aromatic group represented by R¹⁰ and R¹¹ may have a substituent. Examples of such substituents can be the same as those substituents which the aromatic hydrocarbon group, the aromatic heterocyclic group, or the condensed polycyclic aromatic group represented by R¹ to R⁹ may have. These substituents may have further substituents. Examples of such further substituents can be the same as those substituents which the aromatic hydrocarbon group, the aromatic heterocyclic group, or the condensed polycyclic aromatic group represented by R¹ to R⁹ may have. These substituents may form a ring by binding with each other via a single bond, a methylene group that may have a substituent, an oxygen atom, or a sulfur atom.

Examples of the aryloxy group represented by R¹⁰ and R¹¹ can be the same as those of the aryloxy group represented by R¹ to R⁹.

The aryloxy group represented by R¹⁰ and R¹¹ may have a substituent. Examples of such substituents can be the same as those substituents which the aromatic hydrocarbon group, the aromatic heterocyclic group, or the condensed polycyclic aromatic group represented by R¹ to R⁹ may have. These substituents may have further substituents. Examples of such further substituents can be the same as those substituents which the aromatic hydrocarbon group, the aromatic heterocyclic group, or the condensed polycyclic aromatic group represented by R¹ to R⁹ may have. These substituents may form a ring by binding with each other via a single bond, a methylene group that may have a substituent, an oxygen atom, or a sulfur atom.

Ar¹, Ar², and Ar³ may be identical to or different from each other and each represent an aromatic hydrocarbon group, an aromatic heterocyclic group, or a condensed polycyclic aromatic group. The groups of Ar¹, Ar², and Ar³ may form a ring by binding with each other via a single bond, a methylene group that may have a substituent, an oxygen atom, or a sulfur atom. For example, Ar² and Ar³ may form a ring by binding with each other via a single bond, a methylene group that may have a substituent, an oxygen atom, or a sulfur atom.

Examples of the aromatic hydrocarbon group, the aromatic heterocyclic group, or the condensed polycyclic aromatic group represented by Ar¹, Ar², and Ar³ can be the same as those of the aromatic hydrocarbon group, the aromatic heterocyclic group, or the condensed polycyclic aromatic group represented by R¹ to R⁹. It is preferable that the aromatic heterocyclic group represented by Ar¹, Ar², and Ar³ be a sulfur-containing aromatic heterocyclic group such as a thienyl group, a benzothienyl group, a benzothiazolyl group, or a dibenzothienyl group or an oxygen-containing aromatic heterocyclic group such as a furyl group, a benzofuranyl group, a benzoxazolyl group, or a dibenzofuranyl group.

The aromatic hydrocarbon group, the aromatic heterocyclic group, or the condensed polycyclic aromatic group represented by Ar¹, Ar², and Ar³ may have a substituent. Examples of such substituents can be a deuterium atom, a cyano group, a nitro group, halogen atoms such as a fluorine atom, a chlorine atom, a bromine atom, and a iodine atom, linear or branched C1-C6 alkyl groups such as a methyl group, an ethyl group, an n-propyl group, an isopropyl group, an n-butyl group, an isobutyl group, a tert-butyl group, an n-pentyl group, an isopentyl group, a neopentyl group, and an n-hexyl group, linear or branched C1-C6 alkyloxy groups such as a methyloxy group, an ethyloxy group, and a propyloxy group, alkenyl groups such as an allyl group, aryloxy groups such as a phenyloxy group and a tolyloxy group, arylalkyloxy groups such as a benzyloxy group and a phenethyloxy group, aromatic hydrocarbon groups or condensed polycyclic aromatic groups such as a phenyl group, a biphenylyl group, a terphenylyl group, a naphthyl group, an anthracenyl group, a phenanthryl group, a fluorenyl group, an indenyl group, a pyrenyl group, a perylenyl group, a fluoranthenyl group, and a triphenylenyl group, and the like. Other examples can be aromatic heterocyclic groups such as a pyridyl group, a thienyl group, a furyl group, a pyrrolyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzimidazolyl group, a pyrazolyl group, a dibenzofuranyl group, a dibenzothienyl group, and a carbolinyl group, arylvinyl groups such as a styryl group and a naphthylvinyl group, acyl groups such as an acetyl group and a benzoyl group, and the like. Further, these substituents may have further substituents. Examples of such further substituents can be the same as those of the substituent that the aromatic hydrocarbon group or the like represented by Ar¹, Ar², and Ar³ has. Further, either these substituents or these substituents and Ar¹, Ar², and Ar³ may form a ring by binding with each other via a single bond, a methylene group that may have a substituent, an oxygen atom, or a sulfur atom.

It is preferable that Ar¹ be an aromatic hydrocarbon group, a sulfur-containing aromatic heterocyclic group, or a condensed polycyclic aromatic group. It is particularly preferable that Ar¹ be a phenyl group, a biphenyl group, a naphthyl group, a phenanthryl group, a fluorenyl group, a thienyl group, a benzothienyl group, or a dibenzothienyl group. It is most preferable that Ar¹ be a phenyl group, a biphenyl group, a fluorenyl group, a benzothienyl group, or a dibenzothienyl group. It is preferable that Ar² and Ar³ each be an aromatic hydrocarbon group, an oxygen-containing aromatic heterocyclic group, a sulfur-containing aromatic heterocyclic group, or a condensed polycyclic aromatic group. It is particularly preferable that Ar² and Ar³ each be a phenyl group, a biphenylyl group, a terphenylyl group, a naphthyl group, an anthryl group, a phenanthryl group, a fluorenyl group, a triphenylenyl group, a furyl group, a thienyl group, a benzofuranyl group, a benzothienyl group, a dibenzofuranyl group, or a dibenzothienyl group. It is most preferable that Ar² and Ar³ each be a phenyl group, a biphenyl group, a naphthyl group, a phenanthryl group, a fluorenyl group, a triphenylenyl group, a furyl group, a thienyl group, a benzofuranyl group, a benzothienyl group, a dibenzofuranyl group, or a dibenzothienyl group.

A represents either a divalent group of an aromatic hydrocarbon, an aromatic heterocycle, or a condensed polycyclic aromatic compound or a single bond. Examples of such aromatic hydrocarbons, aromatic heterocycles, and condensed polycyclic aromatic compounds can be benzene, biphenyl, terphenyl, tetrakisphenyl, styrene, naphthalene, anthracene, acenaphthalene, fluorene, phenanthlene, indane, pyrene, pyridine, pyrimidine, triazine, furan, pyrrole, thiophene, quinoline, isoquinoline, benzofuran, benzothiophene, indoline, carbazole, carboline, benzoxazole, benzothiazole, quinoxaline, benzimidazole, pyrazole, dibenzofuran, dibenzothiophene, naphthyridine, phenanthroline, acridone, and the like. The divalent group represented by A is formed by removing two hydrogen atoms from the aromatic hydrocarbon, the aromatic heterocycle, or the condensed polycyclic aromatic compound. It is preferable that the aromatic heterocycle be a sulfur-containing aromatic heterocycle such as thiophene, benzothiophene, benzothiazole, or dibenzothiophene or an oxygen-containing aromatic heterocycle such as furane, benzofurane, benzoxazole, or dibenzofurane.

The aromatic hydrocarbon, the aromatic heterocycle, or the condensed polycyclic aromatic compound may have a substituent. Examples of such substituents can be the same as those substituents which the aromatic hydrocarbon group, the aromatic heterocyclic group, or the condensed polycyclic aromatic group represented by Ar¹, Ar², and Ar³ may have. These substituents may have further substituents. Examples of such further substituents can be the same as those substituents which the aromatic hydrocarbon group, the aromatic heterocyclic group, or the condensed polycyclic aromatic group represented by Ar¹, Ar², and Ar³ may have. Further, these substituents may form a ring by binding with each other via a single bond, a methylene group that may have a substituent, an oxygen atom, or a sulfur atom.

It is preferable that A be a divalent group of an aromatic hydrocarbon, a divalent group or single bond of a condensed polycyclic aromatic compound, and it is particularly preferable that A be a divalent group or single bond derived from benzene.

In formula (24), A represents a single bond, a divalent group of an aromatic hydrocarbon, a divalent group of an aromatic heterocycle, or a divalent group of a condensed polycyclic aromatic compound. Ar¹ represents an unsubstituted phenyl group, and Ar² represents an aromatic hydrocarbon group, an aromatic heterocyclic group, or a condensed polycyclic aromatic group. R¹ to R⁹ are identical to or different from each other and each represent a hydrogen atom, a deuterium atom, a fluorine atom, a chlorine atom, a cyano group, a trifluoromethyl group, a C1-C6 alkyl group, an aromatic hydrocarbon group, an aromatic heterocyclic group, or a condensed polycyclic aromatic group. W, X, Y, and Z each represent a carbon atom or a nitrogen atom, only one of W, X, Y, and Z is a nitrogen atom, and the nitrogen atom does not have the hydrogen atoms or substituents of R¹ to R⁴.

In formula (24), A represents a single bond, a divalent group of an aromatic hydrocarbon, a divalent group of an aromatic heterocycle, or a divalent group of a condensed polycyclic aromatic compound. Examples of such aromatic hydrocarbons, aromatic heterocycles, and condensed polycyclic aromatic compounds can be benzene, biphenyl, terphenyl, tetrakisphenyl, styrene, naphthalene, anthracene, acenaphthylene, fluorene, phenanthlene, indane, pyrene, triphenylene, fluoranthene, benzofluoranthene, chrysene, pyridine, pyrimidine, triazine, furan, pyrrole, thiophene, quinoline, isoquinoline, benzofuran, benzothiophene, indoline, carbazole, carboline, benzoxazole, benzothiazole, quinoxaline, benzimidazole, pyrazole, dibenzofuran, dibenzothiophene, naphthyridine, phenanthroline, acridine, bipyridine, phenylpyridine, and the like.

The divalent group of an aromatic hydrocarbon, an aromatic heterocycle, or a condensed polycyclic aromatic compound as represented by A is formed by removing two hydrogen atoms from the aromatic hydrocarbon, the aromatic heterocycle, or the condensed polycyclic aromatic compound. It should be noted that the aromatic hydrocarbon does not have a condensed polycyclic structure. Meanwhile, the aromatic heterocycle may have a condensed polycyclic structure.

The divalent group of an aromatic hydrocarbon, an aromatic heterocycle, or a condensed polycyclic aromatic compound as represented by A may have a substituent. Examples of such substituents can be a deuterium atom, a cyano group, a nitro group, halogen atoms such as a fluorine atom and a chlorine atom, C1-C6 alkyl groups such as a methyl group, an ethyl group, an n-propyl group, an isopropyl group, an n-butyl group, an isobutyl group, a tert-butyl group, an n-pentyl group, an isopentyl group, a neopentyl group, and an n-hexyl group, C1-C6 alkyloxy groups such as a methyloxy group, an ethyloxy group, and a propyloxy group, alkenyl groups such as an allyl group, aryloxy groups such as a phenyloxy group and a tolyloxy group, arylalkyloxy groups such as a benzyloxy group and a phenethyloxy group, aromatic hydrocarbon groups or condensed polycyclic aromatic groups such as a phenyl group, a biphenylyl group, a terphenylyl group, a naphthyl group, an anthracenyl group, a phenanthrenyl group, a fluorenyl group, an indenyl group, a pyrenyl group, a perylenyl group, a fluoranthenyl group, a triphenylenyl group, a tetrakisphenyl group, a styryl group, an acenaphthenyl group, and a phenylnaphthyl group, aromatic heterocyclic groups such as a pyridyl group, a thienyl group, a furyl group, a pyrrolyl group, a quinolyl group, an isoquinolyl group, a benzofuranyl group, a benzothienyl group, an indolyl group, a carbazolyl group, a benzoxazolyl group, a benzothiazolyl group, a quinoxalinyl group, a benzimidazolyl group, a pyrazolyl group, a dibenzofuranyl group, a dibenzothienyl group, a carbolinyl group, a triazinyl group, a pyrimidinyl group, a naphthyridinyl group, a phenanthrolinyl group, and an acridinyl group, arylvinyl groups such as a styryl group and a naphthylvinyl group, acyl groups such as an acetyl group and a benzoyl group, and the like. Of the aforementioned substituents, the C1-C6 alkyl groups and the C1-C6 alkyloxy groups may be linear or branched. The aforementioned substituents may be further substituted by the substituents exemplified above. Further, these substituents may form a ring by binding with each other via a single bond, a substituted or unsubstituted methylene group, an oxygen atom, or a sulfur atom.

In formula (24) Ar¹ and Ar² may be identical to or different from each other and each represent an aromatic hydrocarbon group, an aromatic heterocyclic group, or a condensed polycyclic aromatic group. Examples of the aromatic hydrocarbon group, the aromatic heterocyclic group, or the condensed polycyclic aromatic group represented by Ar¹ and Ar² can be a phenyl group, a biphenylyl group, a terphenylyl group, a tetrakisphenyl group, a styryl group, a naphthyl group, an anthracenyl group, an acenaphthenyl group, a phenanthrenyl group, a triphenylenyl group, a fluorenyl group, an indenyl group, a pyrenyl group, a triazinyl group, a pyridyl group, a pyrimidinyl group, a furyl group, a pyrrolyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalinyl group, a benzimidazolyl group, a pyrazolyl group, a dibenzofuranyl group, a dibenzothienyl group, a naphthyridinyl group, a phenanthrolinyl group, an acridinyl group, a chrysenyl group, a fluoranthenyl group, a benzofluoranthenyl group, and the like.

The aromatic hydrocarbon group, the aromatic heterocyclic group, or the condensed polycyclic aromatic group represented by Ar¹ and Ar² may have a substituent. Examples of such substituents can be the same as those substituents which the divalent group of an aromatic hydrocarbon, an aromatic heterocycle, or a condensed polycyclic aromatic compound as represented by A may have. The same applies to forms that the substituents may take.

In formula (24), R¹ to R⁹ may be identical to or different from each other and each represent a hydrogen atom, a deuterium atom, a fluorine atom, a chlorine atom, a cyano group, a trifluoromethyl group, a C1-C6 alkyl group, an aromatic hydrocarbon group, an aromatic heterocyclic group, or a condensed polycyclic aromatic group. Examples of the C1-C6 alkyl group represented by R¹ to R⁹ can be a methyl group, an ethyl group, an n-propyl group, an iso-propyl group, an n-butyl group, a 2-methylpropyl group, a tert-butyl group, an n-pentyl group, a 3-methylbutyl group, a tert-pentyl group, an n-hexyl group, an iso-hexyl group, a tert-hexyl group, and the like. The C1-C6 alkyl group may be linear or branched.

Examples of the aromatic hydrocarbon group, the aromatic heterocyclic group, or the condensed polycyclic aromatic group represented by R¹ to R⁹ can be the same as those of the aromatic hydrocarbon group, the aromatic heterocyclic group, or the condensed polycyclic aromatic group represented by Ar¹ and Are.

The aromatic hydrocarbon group, the aromatic heterocyclic group, or the condensed polycyclic aromatic group represented by R¹ to R⁹ may have a substituent. Examples of such substituents can be the same as those substituents which the divalent group of an aromatic hydrocarbon, an aromatic heterocycle, or a condensed polycyclic aromatic compound as represented by A may have. The same applies to forms that the substituents may take.

In formula (24), W, X, Y, and Z each represent a carbon atom or a nitrogen atom, and only one of W, X, Y, and Z is a nitrogen atom (and the remaining three are carbon atoms). In a case where only one of W, X, Y, and Z is a nitrogen atom, the nitrogen atom does not have the hydrogen atoms or substituents of R¹ to R⁴. That is, in a case where W is a nitrogen atom, R¹ does not exist. In a case where X is a nitrogen atom, R² does not exist. In a case where Y is a nitrogen atom, R³ does not exist. In a case where Z is a nitrogen atom, R⁴ does not exist.

In a benzopyridoindole derivative of the present invention as represented by formula (24), it is preferable that A be a divalent group of an aromatic hydrocarbon having one or two rings, a divalent group of an aromatic heterocycle having one or two rings, or a divalent group or single bond of naphthalene. Examples of the aromatic hydrocarbon having one or two rings and the aromatic heterocycle having one or two rings can be benzene, biphenyl, styrene, indane, pyridine, pyrimidine, triazine, furane, pyrrole, thiophene, quinoline, isoquinoline, benzofurane, benzothiophene, indoline, benzoxazole, benzothiazole, quinoxaline, benzimidazole, pyrazole, naphthyridine, bipyridine, phenylpyridine, and the like. Furthermore, it is preferable that A be a divalent group of an aromatic hydrocarbon having one or two rings or a divalent group or single bond of naphthalene. It is more preferable that A be a divalent group or single bond formed by removing two hydrogen atoms from benzene, biphenyl, or naphthalene. It is more particularly preferable that A be a divalent group or single bond formed by removing two hydrogen atoms from benzene or biphenyl.

It is preferable that Ar¹ be an aromatic hydrocarbon group, a condensed polycyclic aromatic group, a sulfur-containing aromatic heterocyclic group such as a dibenzothienyl group, or an oxygen-containing aromatic heterocyclic group such as a dibenzofuranyl group. From the perspective of the bipolarity of the compound, it is more preferable that Ar¹ be a phenyl group and it is particularly preferable that Ar¹ be an unsubstituted phenyl group.

It is preferable that Ar² be an aromatic hydrocarbon group having three or more rings, an aromatic heterocyclic group having three or more rings, and a tricyclic or more condensed polycyclic aromatic group. Examples of the aromatic hydrocarbon group having three or more rings, the aromatic heterocyclic group having three or more rings, and the tricyclic or more condensed polycyclic aromatic group can be a terphenylyl group, a tetrakisphenyl group, an anthracenyl group, an acenaphthenyl group, a phenanthrenyl group, a triphenylenyl group, a fluorenyl group, a pyrenyl group, a carbazolyl group, a dibenzofuranyl group, a dibenzothienyl group, a phenanthrolinyl group, an acridinyl group, a chrysenyl group, a fluoranthenyl group, a benzofluoranthenyl group, and the like. Furthermore, from the perspective of imparting charge polarization to the benzopyridoindole derivative, it is preferable that Ar² be an aromatic hydrocarbon group having three or more rings, a tricyclic or more condensed polycyclic aromatic group, a dibenzothienyl group, a carbazolyl group, a phenanthrolinyl group, or a dibenzofuranyl group, it is more preferable that Ar² be an aromatic hydrocarbon group having three or more rings or a tricyclic or more condensed polycyclic aromatic group, and it is particularly preferable that Ar² be an anthracenyl group. It is preferable that the anthracenyl group has a substituent, although it may be unsubstituted or have a substituent.

It is preferable that an example of a substituent that Ar² may have be an aromatic hydrocarbon group, a condensed polycyclic aromatic group, or an aromatic heterocyclic group, such as a phenyl group, a biphenylyl group, a terphenylyl group, a tetrakisphenyl group, a styryl group, a naphthyl group, an anthracenyl group, an acenaphthenyl group, a phenanthrenyl group, a fluorenyl group, an indenyl group, a pyrenyl group, a pyridyl group, a triazinyl group, a pyrimidinyl group, a furyl group, a pyrrolyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalinyl group, a benzimidazolyl group, a pyrazolyl group, a dibenzofuranyl group, a dibenzothienyl group, a naphthyridinyl group, a phenanthrolinyl group, or an acridinyl group, and it is more preferable that an example of a substituent that Ar² may have be a phenyl group, a biphenylyl group, a naphthyl group, a phenanthrenyl group, a fluorenyl group, a pyridyl group, a triazinyl group, a pyrimidinyl group, a quinolyl group, an isoquinolyl group, a dibenzofuranyl group, or a dibenzothienyl group. From the perspective of imparting charge polarization to the benzopyridoindole derivative, it is particularly preferable that an example of a substituent that Ar² may have be a phenyl group or a naphthyl group.

For ease of synthesis, it is preferable that R¹ to R⁹ each be a C1-C6 alkyl group or a hydrogen atom and it is particularly preferable that all of R¹ to R⁹ be hydrogen atoms.

It is preferable that, of W, X, Y, and Z, Y be a nitrogen atom.

The luminescent dopant part may be selected from a group consisting of, but is not limited to, compounds represented by formulae (27) to (31):

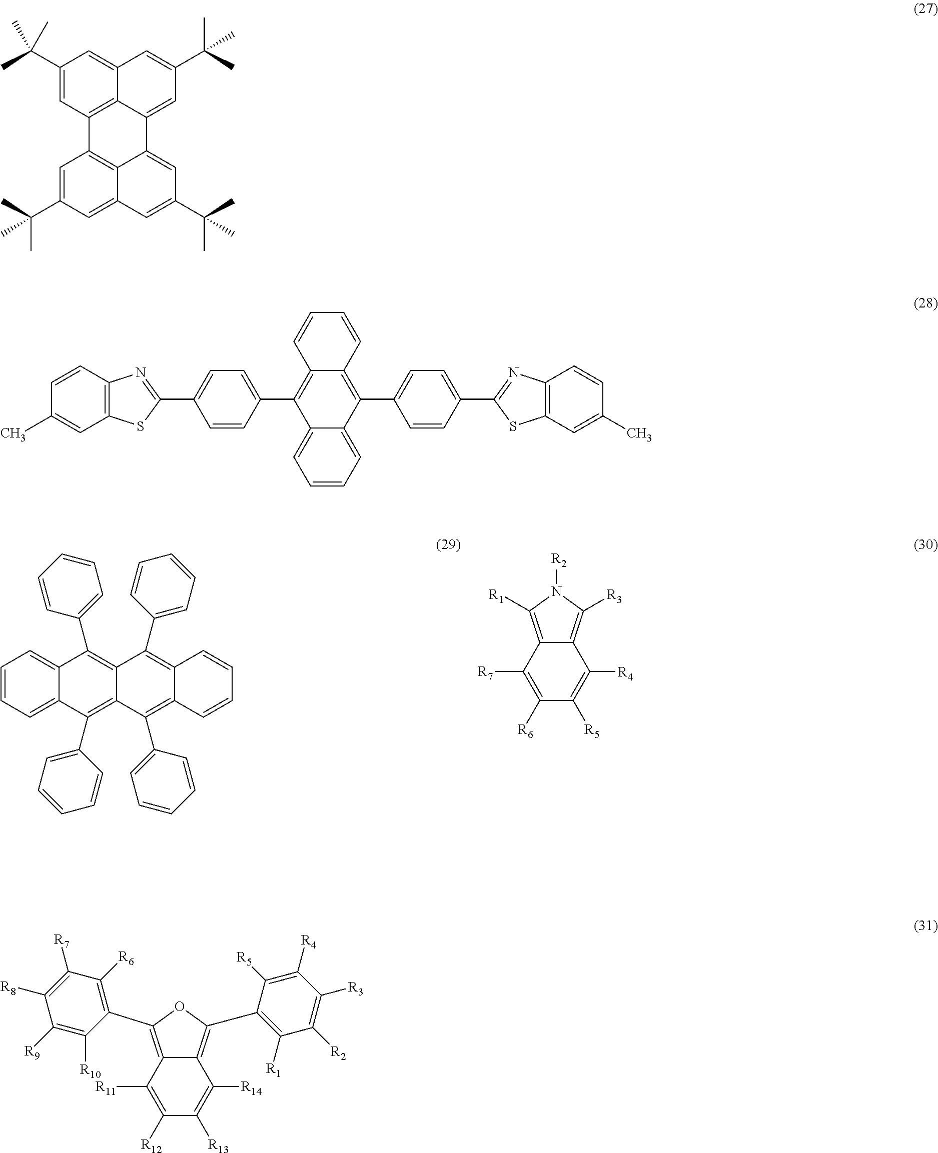

In formula (30), R¹ to R⁷ is each selected from among hydrogen, an alkyl group, a cycloalkyl group, an aralkyl group, an alkenyl group, a cycloalkenyl group, an alkynyl group, a hydroxyl group, a mercapto group, an alkoxy group, an alkylthio group, an arylether group, an arylthioether group, an aryl group, a heterocyclic group, halogen, haloalkane, haloalkene, haloalkine, a cyano group, an aldehyde group, a carbonyl group, a carboxyl group, an ester group, a carbamoyl group, an amino group, a nitro group, a silyl group, and a siloxanyl group. Further, R¹ to R⁷ may each form a ring structure with an adjacent substituent.

In formula (30), the alkyl group refers to a saturated aliphatic hydrocarbon group such as a methyl group, an ethyl group, a propyl group, or a butyl group, and this may be unsubstituted or substituted. Further, the cycloalkyl group refers to a saturated alicyclic hydrocarbon group such as cyclopropyl, cyclohexyl, norbornyl, or adamantyl, and this may be unsubstituted or substituted. Further, the aralkyl group refers to an aromatic hydrocarbon group via an aliphatic hydrocarbon, such as a benzyl group or a phenylethyl group, and the aliphatic hydrocarbon and the aromatic hydrocarbon may both be unsubstituted or substituted. Further, the alkenyl group refers to an unsaturated aliphatic hydrocarbon group including a double bond, such as a vinyl group, an allyl group, or a butadienyl group, and this may be unsubstituted or substituted. Further, the cycloalkenyl group refers to an unsaturated alicyclic hydrocarbon group including a double bond, such as a cyclopentenyl group, a cyclopentadienyl group, or a cyclohexane group, and this may be unsubstituted or substituted. Further, the alkynyl group refers to an unsaturated aliphatic hydrocarbon group including a triple bond, such as an acetylenyl group, and this may be unsubstituted or substituted.

Further, the alkoxy group refers to an aliphatic hydrocarbon group via an ether bond, such as a methoxy group, and the aliphatic hydrocarbon group may be unsubstituted or substituted. Further, the alkylthio group refers to a group formed by substituting an oxygen atom of an ether bond of an alkoxy group with a sulfur atom. Further, the arylether group refers to an aromatic hydrocarbon group via an ether bond, such as a phenoxy group, and the aromatic hydrocarbon group may be unsubstituted or substituted. Further, the arylthioether group refers to a group formed by substituting an oxygen atom of an ether bond of an arylether group with a sulfur atom. Further, the aryl group refers to an aromatic hydrocarbon group such as a phenyl group, a naphthyl group, a biphenyl group, a phenanthryl group, a terphenyl group, or a pyrenyl group, and this may be unsubstituted or substituted. Further, the heterocyclic group refers to a ring structure group having atoms other than carbon atoms, such as a furyl group, a thienyl group, an oxazolyl group, a pyridyl group, a quinolyl group, or a carbazolyl group, and this may be unsubstituted or substituted. The halogen refers to fluorine, chlorine, bromine, and iodine.

The haloalkane, the haloalkene, and the haloalkine refer to groups, such as a trifluoromethyl group, formed by substituting some or all of the alkyl group, the alkenyl group, and the alkynyl group with the halogen, and the remaining parts may be unsubstituted or substituted. The aldehyde group, the carbonyl group, the ester group, the carbamolyl group, and the amino group include those substituted by an aliphatic hydrocarbon, an alicyclic hydrocarbon, an aromatic hydrocarbon, a heterocycle, or the like, and furthermore, the aliphatic hydrocarbon, the alicyclic hydrocarbon, the aromatic hydrocarbon, and the heterocycle may be unsubstituted or substituted. The silyl group refers to a silicon compound group such as a trimethylsilyl group, and this may be unsubstituted or substituted. The siloxanyl group refers to a silicon compound group via an ether bond, such as a trimethylsiloxanyl group, and this may be unsubstituted or substituted. Further, a ring structure may be formed with an adjacent substituent. The ring structure that is formed may be unsubstituted or substituted.

In formula (31), R¹ to R¹⁴ may be identical to or different from each other and is each selected from among hydrogen, an alkyl group, a cycloalkyl group, an aralkyl group, an alkenyl group, a cycloalkenyl group, an alkynyl group, an alkoxy group, an alkylthio group, an arylether group, an arylthioether group, an aryl group, a heterocyclic group, halogen, haloalkane, an amino group, a silyl group, a siloxanyl group, a condensed ring that is formed with an adjacent substituent, a heterocycle, and an aliphatic ring.

In the description of these substituents, the alkyl group refers to a saturated aliphatic hydrocarbon group such as a methyl group, an ethyl group, a propyl group, or a butyl group, and this may be unsubstituted or substituted. Further, the cycloalkyl group refers to a saturated alicyclic hydrocarbon group such as cyclopropyl, cyclohexyl, norbornyl, or adamantyl, and this may be unsubstituted or substituted. Further, the aralkyl group refers to an aromatic hydrocarbon group via an aliphatic hydrocarbon, such as a benzyl group or a phenylethyl group, and the aliphatic hydrocarbon and the aromatic hydrocarbon may both be unsubstituted or substituted. Further, the alkenyl group refers to an unsaturated aliphatic hydrocarbon group including a double bond, such as a vinyl group, an allyl group, or a butadienyl group, and this may be unsubstituted or substituted. Further, the cycloalkenyl group refers to an unsaturated alicyclic hydrocarbon group including a double bond, such as a cyclopentenyl group, a cyclopentadienyl group, or a cyclohexane group, and this may be unsubstituted or substituted. Further, the alkynyl group refers to an unsaturated aliphatic hydrocarbon group including a triple bond, such as an acetylenyl group, and this may be unsubstituted or substituted. Further, the alkoxy group refers to an aliphatic hydrocarbon group via an ether bond, such as a methoxy group, and the aliphatic hydrocarbon group may be unsubstituted or substituted. Further, the alkylthio group refers to a group formed by substituting an oxygen atom of an ether bond of an alkoxy group with a sulfur atom. Further, the arylether group refers to an aromatic hydrocarbon group via an ether bond, such as a phenoxy group, and the aromatic hydrocarbon group may be unsubstituted or substituted. Further, the arylthioether group refers to a group formed by substituting an oxygen atom of an ether bond of an arylether group with a sulfur atom. Further, the aryl group refers to an aromatic hydrocarbon group such as a phenyl group, a naphthyl group, a biphenyl group, a phenanthryl group, a terphenyl group, or a pyrenyl group, and this may be unsubstituted or substituted. Further, the heterocyclic group refers to a ring structure group having atoms other than carbon atoms, such as a furyl group, a thiophenyl group, an oxazolyl group, a pyridyl group, a quinolyl group, or a carbazolyl group, and this may be unsubstituted or substituted. The halogen refers to fluorine, chlorine, bromine, and iodine. The haloalkane, the haloalkene, and the haloalkine refer to groups, such as a trifluoromethyl group, formed by substituting some or all of the alkyl group, the alkenyl group, and the alkynyl group with the halogen, and the remaining parts may be unsubstituted or substituted. The aldehyde group, the carbonyl group, the ester group, the carbamolyl group, and the amino group include those substituted by an aliphatic hydrocarbon, an alicyclic hydrocarbon, an aromatic hydrocarbon, a heterocycle, or the like, and furthermore, the aliphatic hydrocarbon, the alicyclic hydrocarbon, the aromatic hydrocarbon, and the heterocycle may be unsubstituted or substituted. The silyl group refers to a silicon compound group such as a trimethylsilyl group, and this may be unsubstituted or substituted. The siloxanyl group refers to a silicon compound group via an ether bond, such as a trimethylsiloxanyl group, and this may be unsubstituted or substituted.

The following shows examples of a mode of binding between the assist dopant part and the luminescent dopant part in the material for organic electroluminescent display device according to the present invention. As one example, a description is given using the compound (ACRSA) of formula (7) or the compound (2CzON) of formula (8) as the assist dopant part and the compound (TBPe) of formula (27) as the luminescent dopant part.

For example, in a case where the compound (ACRSA) of formula (7) and the compound (TBPe) of formula (27) are linked by a single bond, the mode of binding between the compound (ACRSA) of formula (7) and the compound (TBPe) of formula (27) is represented by, but is not limited to, formula (32):

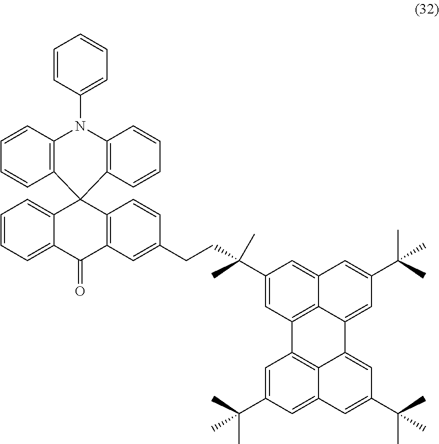

For example, in a case where the compound (2CzON) of formula (8) and the compound (TBPe) of formula (27) are linked by a single bond, the mode of binding between the compound (2CzON) of formula (8) and the compound (TBPe) of formula (27) is represented by, but is not limited to, formula (33):

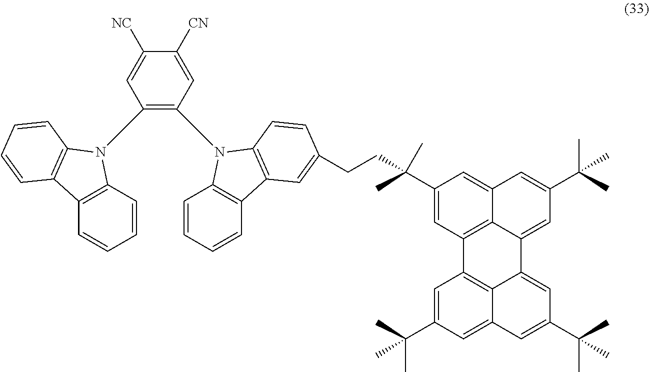

The mode of binding between the assist dopant part and the luminescent dopant part can be arbitrarily set, provided it can assume any of the configurations represented by formulae (1) to (6) above.

In an embodiment, it is preferable that the material for organic electroluminescent display device according to the present invention having the aforementioned characteristics be a blue fluorescent material having an energy of 2.7 eV or higher in the excited singlet state S₁ level. Further, it is preferable that the energy gap ΔE_{ST} between the excited singlet state S₁ and the excited triplet state T₁ be 0.03 eV. It is preferable that the material for organic electroluminescent display device according to the present invention be a blue fluorescent material having a wavelength of 490 nm to 440 nm at which the internal quantum yield exceeds theoretical 25% and falls within a range of up to 100%.

The material for organic electroluminescent display device according to the present invention can be used in combination with a host material having an energy of 2.8 eV or higher in the excited triplet state T₁ level and an energy in the excited singlet state S₁ level that is higher than that of the assist dopant part in the excited singlet state S₁ by +0.4 eV or more. For high efficiency in the transfer of energy to and from the material for organic electroluminescent display device according to the present invention, it is preferable that the host material fall within the above level energy ranges. It should be noted that the host material that is combined may be a publicly-known one, provided it satisfies the above requirements.

For energy delivery, an assist dopant part needs to be present near a fluorescent dopant. However, since a luminescent layer has conventionally been formed by three-source vapor deposition, it has been difficult to control the configuration of the fluorescent dopant and the assist dopant. In the present invention, the use of a compound in which an assist dopant and a luminescent dopant are bound makes it possible to control the ratio of combination and the molecular distance to improve the light emission efficiency and makes it possible to stably supply a material for organic electroluminescent display device.

### (Configuration of Organic Electroluminescent Display Device)

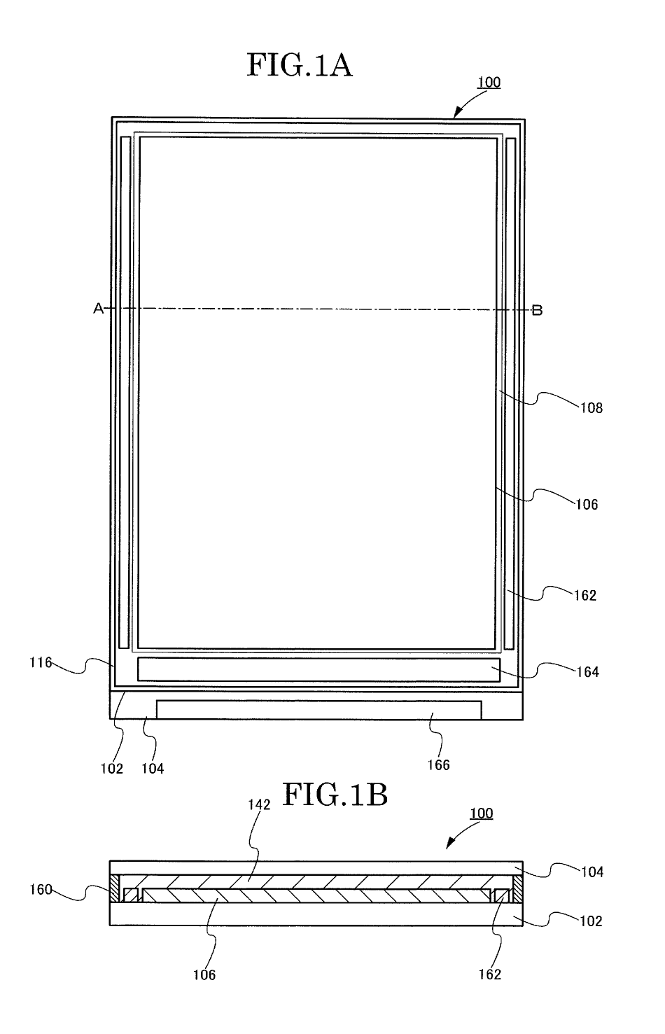

A configuration of an organic electroluminescent display device according to an embodiment of the present invention is described below with reference to FIGS. 1A and 1B. FIG. 1A is a plan view of an organic electroluminescent display device 100, and FIG. 1B is a sectional view taken along line A-B in FIG. 1A.

The organic electroluminescent display device 100 includes a pixel unit 106 in which a plurality of pixels are two-dimensionally arrayed. The pixel unit 106 is provided on a first substrate 102. The first substrate 102 may be provided with a scanning line drive circuit 162, a video signal line drive circuit 164, an input terminal unit 166, and the like. A second substrate 104 is provided opposite the first substrate 102 so as to seal the pixel unit 106.

The first substrate 102 and the second substrate 104 are fixed by a seal member 160. The second substrate 104 and the first substrate 102 are fixed with a space of several micrometers to several tens of micrometers therebetween, and in the space, a filling material 142 is provided. As the filling material 142, a resin material is suitably used. Such a configuration in which the pixel unit 106 is sandwiched between the second substrate 104 and the first substrate 102 and the space between the second substrate 104 and the first substrate 102 is filled with the filling material 142 is called “solid sealing”.

Each of the pixels in the pixel unit 106 is provided with a light-emitting element. The light-emitting element has a luminescent layer containing a host material described above that is used as an organic EL material and a material for organic electroluminescent display device according to the present invention. Emission of light from each of the pixels in the pixel unit 106 is individually controlled by a pixel circuit. Signals that control emission of light from each separate pixel are supplied from the scanning line drive circuit 162 and the video signal line drive circuit 164.

The organic electroluminescent display device 100 shown in FIGS. 1A and 1B has a top-emission type configuration in which light emitted from the pixel unit 106 exits toward the second substrate 104.

It should be noted that, in the case of a top-emission type, the second substrate 104 is made from glass or a resin material, as the second substrate 104 needs to have translucency. A preferred highly translucent resin material is one selected from polybenzoxazole, polyamideimide having an alicyclic structure, polyimide having an alicyclic structure, polyamide, and poly(p-xylylene). Each of these resin materials may be used alone, or plural types of these resin materials may be used in combination. For example, in a case where the second substrate 104 is made from polyimide resin, the second substrate 104 can be formed by applying polyamic acid (including partially-imidized polyamide acid), which is a precursor to polyimide, or a solution containing soluble polyimide to a support substrate 152 and then firing the support substrate 152.

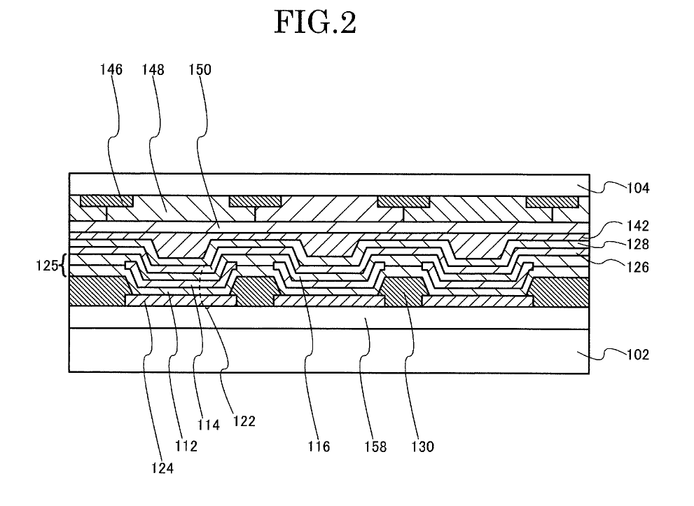

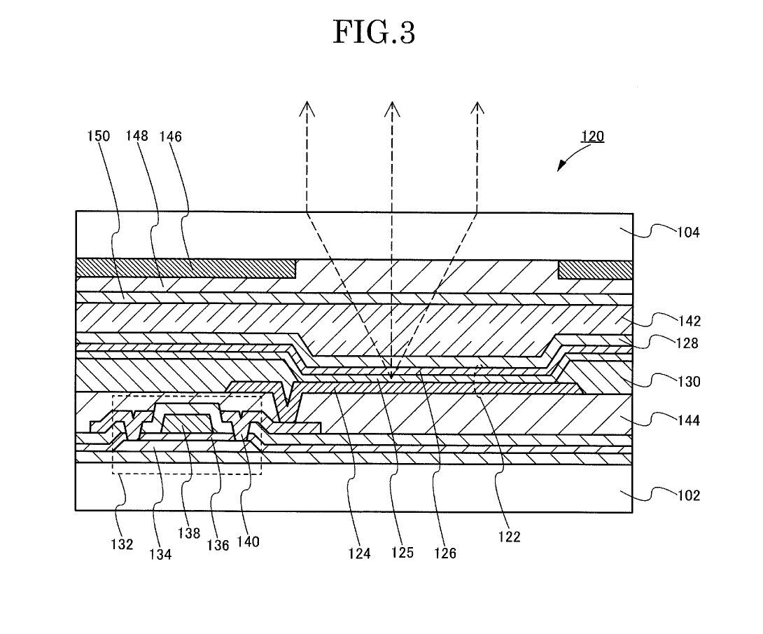

A configuration of the pixel unit 106 is described with reference to FIGS. 2 and 3. FIG. 2 is a sectional view showing the arrangement of an organic EL element 122 in the pixel unit 106. FIG. 3 is a sectional view showing the arrangement of a pixel 120 in a pixel unit 106. The organic EL element 122 includes a pixel electrode (first electrode layer) 124, an organic EL layer 125 stacked on the pixel electrode 124, and a common electrode (second electrode layer) 126 stacked on the organic EL layer 125. The organic EL layer 125 can be made from a low-molecular or high-molecular organic material. The organic EL layer 125 includes a luminescent layer 114 and electron transport layers such as a hole transport layer 112 and an electron transport layer 116. The luminescent layer 114 contains a host material and a material for organic electroluminescent display device according to the present invention. The luminescent layer 114 is sandwiched between the hole transport layer 112 and the electron transport layer 116. Further, the organic EL layer 125 may be one that emits red (R), green (G), and blue (B) lights, or may be one that exhibits so-called white light emission. In a case where the organic EL layer 125 emits red (R), green (G), and blue (B) lights, the organic EL layer 125 can be formed by giving the different colors to each separate pixel with materials for organic electroluminescent display device each including an assist dopant and a luminescent dopant that emits a corresponding one of the colors of light.

Further, in an embodiment, the organic EL layer 125 may include a hole-injection layer disposed between the pixel electrode 124 and the hole transport layer 112 and an electron-injection layer disposed between the common electrode 126 and the electron transport layer 116.

It should be noted that, in the present embodiment, publicly-known materials can be used as materials from which the hole transport layer 112, the luminescent layer 114, the electron transport layer 116, the hole-injection layer, and the electron-injection layer are made.

Examples of a hole-transporting material from which the hole transport layer 112 and the hole-injection layer are made include heterocyclic conjugated monomers, oligomers, polymers, and the like of benzidine or a derivative thereof, styrylamine or a derivative thereof, triphenylmethane or a derivative thereof, porphyrin or a derivative thereof, triazole or a derivative thereof, imidazole or a derivative thereof, oxadiazole or a derivative thereof, polyarylalkane or a derivative thereof, phenylenediamine or a derivative thereof, arylamine or a derivative thereof, oxazole or a derivative thereof, anthracene or a derivative thereof, fluorenone or a derivative thereof, hydrazone or a derivative thereof, a stilbene or a derivative thereof, phthalocyanine or a derivative thereof, a polysilane compound, a vinylcarbazole compound, a thiophene compound, an aniline compound, and the like.

Specific examples of such hole-transporting materials include, but are not limited to, α-naphthylphenyldiamine (αNPD), porphyrin, metallic tetraphenyl porphyrin, metallic naphthalocyanine, 4,4′,4″-trimethyltriphenylamine, 4,4′,4″-tris(3-methylphenylphenylamino)triphenylamine (m-MTDATA), N,N,N′,N′-tetrakis(p-tolyl)p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophenevinylene), poly(2,2′-thienylpyrrole), and the like.

Examples of materials that can be used as an electron-transporting material from which the electron transport layer 116 and the electron-injection layer are made include, but are not limited to, 8-hydroxylquinolinealuminum (Alq₃), 8-hydroxymethylquinolinealuminum, anthracene, naphthalene, phenanthrene, pyrene, chrysene, perylene, butadiene, coumalin, acridine, stilbene, derivatives thereof, and the like.

The luminescent layer 114 is constituted by a combination of host materials selected as needed from among the aforementioned hole-transporting materials, the aforementioned electron-transporting materials, and hole-and-electron-transporting materials. Furthermore, according to the arrangement of the pixels, the luminescent layer 114 can contain a material for organic electroluminescent display device according to the present invention. It is preferable that the host material be a material having a energy of 2.8 eV or higher in the excited triplet state T₁ level and a energy in the excited singlet state S₁ level that is higher than that of the assist dopant part in the excited singlet state S₁ by +0.4 eV or more. For high efficiency in the transfer of energy to and from the material for organic electroluminescent display device according to the present invention, it is preferable that the host material fall within the above level energy ranges.

Examples of materials from which the pixel electrode 124 can be made include, but are not limited to, nickel, silver, gold, platinum, palladium, selenium, rhodium, ruthenium, iridium, rhenium, tungsten, molybdenum, chromium, tantalum, niobium, alloys thereof, tin oxide (SnO₂), indium tin oxide (ITO), zinc oxide, titanium oxide, and the like. Further, examples of materials from which the common electrode 126 can be made include, but are not limited to, alloys of an active metal such as Li, Mg, or Ca and a metal such as Ag, Al, or In and structures in which these alloys are stacked.

The arrangement of the pixel 120 in the pixel unit 160 is further described with reference to FIG. 3. The pixel 120 includes the organic EL element 122 and a transistor 132. The pixel electrode 124 has its outer edge covered with a bank layer 130, and the organic EL layer 125 is provided across an area extending from an upper surface of the pixel electrode 124 to the bank layer 130. Further, a sealing film 128 may be provided on an upper surface side of the organic EL element 122. The sealing film 128 is provided so as to cover substantially a front surface of the pixel unit 106.

In the present embodiment, for the top-emission type pixel configuration, it is preferable that the organic EL element 122 be arranged such that the common electrode 126 is translucent and the pixel electrode 124 is provided with a light-reflecting surface. Since light emitted from the organic EL layer 125 is sent out in all directions of 47 on a solid angle basis, light sent out toward the second substrate 104 is a mixture of at least a component of light directly sent out from the organic EL layer 125 and a component of light reflected by the pixel electrode 124 and sent out toward the second substrate 104. In either case, the light emitted from the organic EL layer 125 is incident on the second substrate 104 at various angles.

A current flowing through the organic EL element 122 is controlled by applying, to the common electrode 126, an electric potential that is common to the plurality of pixels and applying, to the pixel electrode 124, an electric potential intended for a corresponding one of the pixels. The electric potential of the pixel electrode 124 is controlled by the transistor 132.

The transistor 132 is a field-effect transistor in which a semiconductor layer 134 and a gate electrode 138 are insulated from each other by a gate insulating layer 136. Specifically, the transistor 132 takes the form of a thin-film transistor in which a channel is formed in the thin-film semiconductor layer 134. It is preferable that an interlayer insulating layer 144 be provided between the transistor 132 and the organic EL element 122, and the pixel electrode 124 is provided on the interlayer insulating layer 144 and connected to a source-drain electrode 140 via a contact hole.

It should be noted that in a case where the organic EL element 122 emits white light, the second substrate 104 may be provided with a light-blocking layer 146, a color filter layer 148, and an overcoat layer 150. Such an arrangement makes a color display possible.

The organic electroluminescent display device 100 of the present embodiment makes it possible, by including an optical element 108 integrated with a sealing substrate and provided on a surface side (display screen side) thereof from which light from the pixel unit 106 exits, to increase efficiency in the extraction of light while achieving a reduction in thickness. Next, a method for manufacturing such a material for organic electroluminescent display device is described.

### (Manufacturing Method)

The following provides a brief overview of a method for manufacturing a material for organic electroluminescent display device according to an embodiment of the present invention. Publicly-known manufacturing processes can be used as processes for manufacturing the material for organic electroluminescent display device.

First, a pixel circuit is formed on a first substrate. At this point in time, a scanning line drive circuit, a video signal line drive circuit, an input terminal unit, and the like are formed as needed. Elements, such as transistors and capacitors, that constitute the pixel circuit are fabricated by repeating stacking of thin films of semiconductor, insulator, and metal and photolithographic patterning.

Light-emitting elements are formed on a circuit element layer 158 on which the pixel circuit and the like have been formed. In order to form organic EL elements for each separate pixel, pixel electrodes that are electrically connected to the pixel circuit are formed. The pixel electrodes are formed on an interlayer insulating layer in which transistors are embedded. Next, a bank layer that covers the outer edges of the pixel electrodes is formed. The pixel electrodes are formed for each separate pixel and have their outer edges surrounded by the bank layer, whereby a region of each pixel is defined.

A hole transport layer, a luminescent layer, and an electron transport layer are formed above the pixel electrodes. Each of these layers can be formed by a vapor-deposition technique or an ink-jet printing technique. Further, in an embodiment, a hole-injection layer may be formed between the pixel electrodes and the hole transport layer, and an electron-injection layer may be formed between a common electrode and the electron transport layer. In this way, an organic EL layer can be formed.

The luminescent layer can be formed by two-source vapor deposition of a host material selected as needed from among the aforementioned hole-transporting materials, the aforementioned electron-transporting materials, and hole-and-electron-transporting materials and, according to the arrangement of the pixels, a material for organic electroluminescent display device according to the present invention. Further, the organic EL layer can be formed by giving different colors of material to each separate pixel by two-source vapor deposition or an ink-jet printing technique.

Furthermore, the common electrode is formed. A sealing film is formed by a silicon nitride film on the common electrode. In this way, the pixel circuit and a pixel unit can be formed.

1. A material for organic electroluminescent display device comprising:
a luminescent dopant part; and
an assist dopant part.

2. The material for organic electroluminescent display device according to claim 1, wherein
the luminescent dopant part has an energy of 2.6 eV or higher to 3.0 eV or lower in an excited singlet state S₁ level,
the assist dopant part has an energy of 2.4 eV or higher to 3.0 eV or lower in the excited singlet state S₁ level, and
an energy gap ΔE_{ST} between the excited singlet state S₁ and an excited triplet state T₁ is 0 eV or larger to 2.0 eV or smaller.

3. The material for organic electroluminescent display device according to claim 1, wherein
the material is selected from a group consisting of compounds represented by formulae (1) to (6): 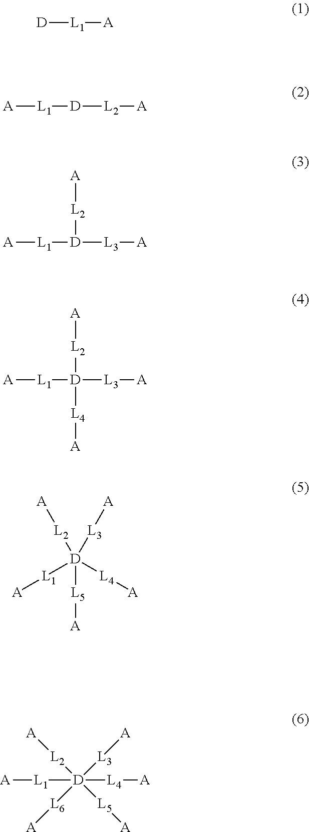
wherein D represents the luminescent dopant part; A represents the assist dopant part; and L is selected from a group consisting of a single bond, a nitrogen atom, an oxygen atom, a sulfur atom, a substituted or unsubstituted divalent hydrocarbon group, a substituted or unsubstituted divalent hydrocarbon group including one or more double bonds, a substituted or unsubstituted divalent hydrocarbon group including one or more triple bonds, and a substituted or unsubstituted divalent hydrocarbon group including one or more double bonds and triple bonds.

4. The material for organic electroluminescent display device according to claim 3, wherein
the assist dopant part is selected from a group consisting of substituents represented by formulae (7) to (24): 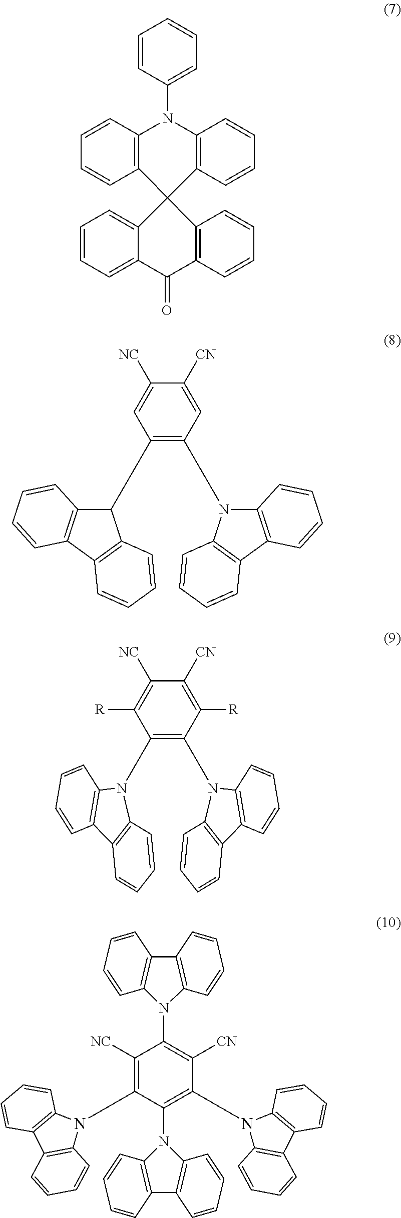 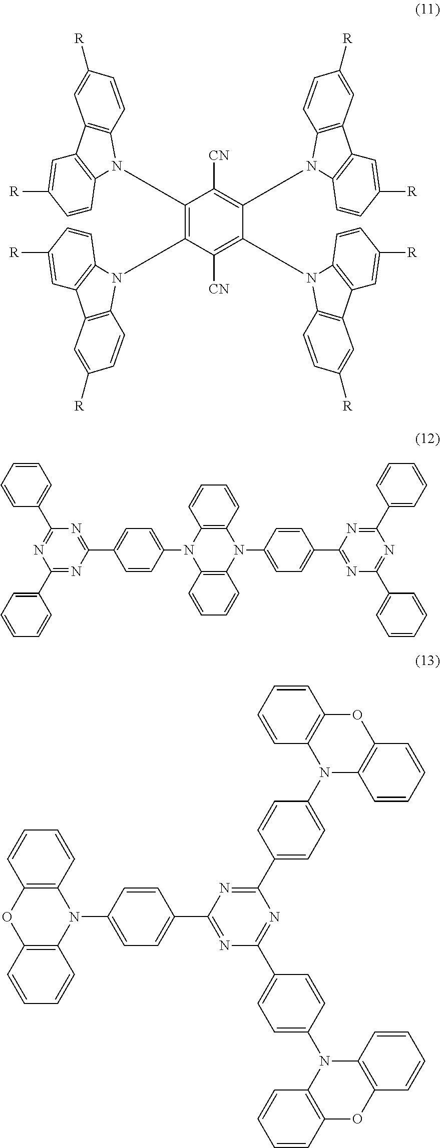 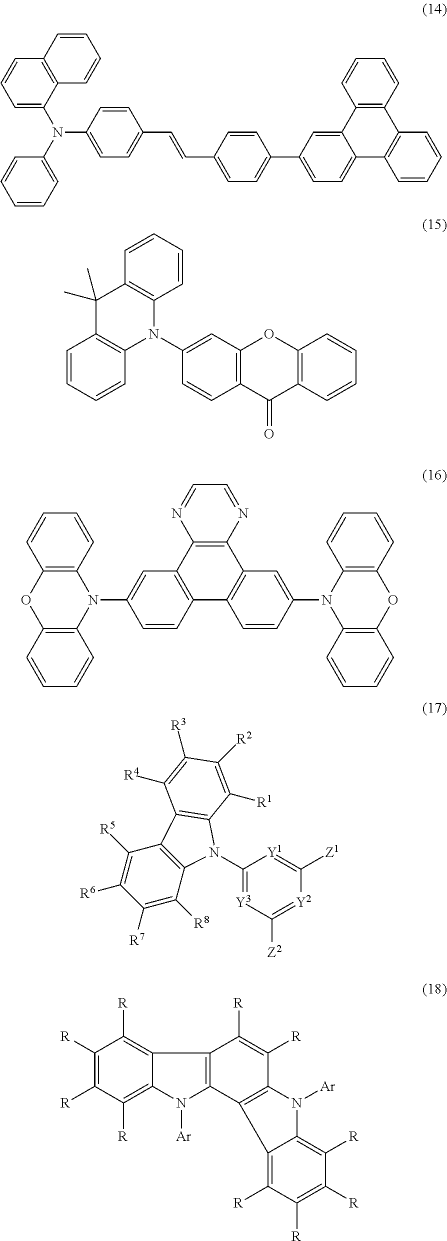 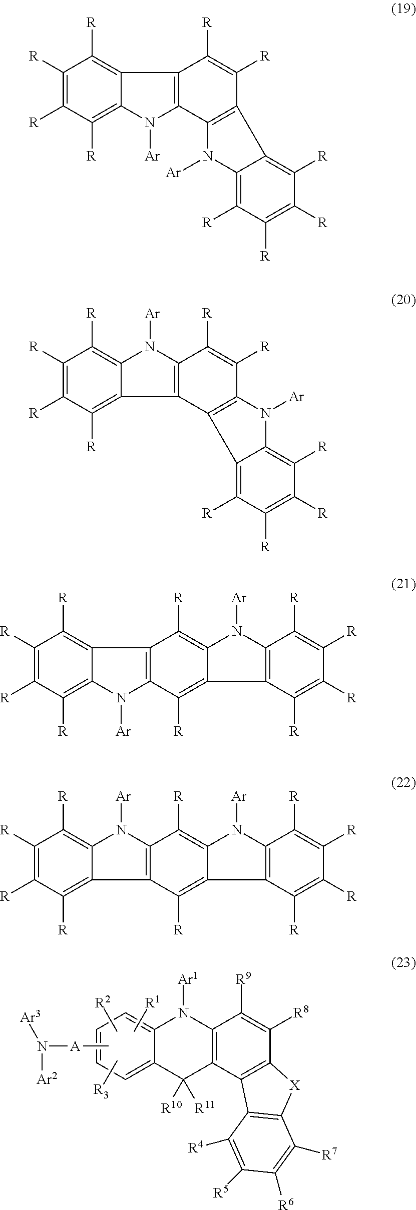 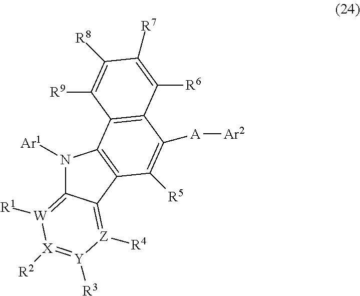
wherein, in formula (9), R represents a hydrogen atom or a carbazolyl group;
in formula (11), R represents a hydrogen atom, a methyl group, or a phenyl group;
in formula (17), R is selected from a group consisting of a hydrogen atom, a methyl group, and a phenyl group, Y² and Y³ represent nitrogen atoms and Y¹ represents a methine group or all of Y¹, Y², and Y³ represent nitrogen atoms, Z¹ and Z² independently represent a hydrogen atom or a substituent, Z² is selected from a group consisting of a hydrogen atom, a substituted or unsubstituted alkyl group, and a substituted or unsubstituted aryl group when Y² and Y³ are nitrogen atoms and Y¹ is a methine group, R¹ to R⁸ independently represent a hydrogen atom or a substituent, at least one of R¹ to R⁸ represents a substituted or unsubstituted diarylamino group or a substituted or unsubstituted carbazolyl group, and at least one of R¹ to R⁸ represents a substituted or unsubstituted diarylamino group or a substituted or unsubstituted 9-carbazolyl group and includes at least two carbazole structures when all of Y¹, Y², and Y³ are nitrogen atoms;
in formulae (18) to (22), each Ar independently represents an aromatic hydrocarbon group or an aromatic heterocyclic group and each R independently represents hydrogen or a monovalent substituent and includes a structure forming or unforming a ring by combining adjacent substituents;
in formula (23), X represents an oxygen atom or a sulfur atom, R¹ to R⁹ are selected from a group consisting of a hydrogen atom, a deuterium atom, a fluorine atom, a chlorine atom, a cyano group, a nitro group, a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, and an aryloxy group and have structures forming or unforming a ring by binding with each other via a single bond, a methylene group, an oxygen atom, or a sulfur atom, R¹⁰ and R¹¹ are selected from a group consisting of a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, and an aryloxy group and have structures forming or unforming a ring by binding with each other via a single bond, a methylene group, an oxygen atom, or a sulfur atom, Ar¹, Ar², and Ar³ are selected from a group consisting of an aromatic hydrocarbon group, an aromatic heterocyclic group, and a condensed polycyclic aromatic group, Ar² and Ar³ have structures forming or unforming a ring by binding with each other via a single bond, a methylene group, an oxygen atom, or a sulfur atom, A represents either a divalent group of an aromatic hydrocarbon, an aromatic heterocycle, or a condensed polycyclic aromatic compound or a single bond, and in a case where A is a divalent group of an aromatic hydrocarbon, an aromatic heterocycle, or a condensed polycyclic aromatic compound, A and Ar² have structures forming or unforming a ring by binding with each other via a single bond, a methylene group, an oxygen atom, or a sulfur atom; and
in formula (24), A is selected from a group consisting of a single bond, a divalent group of an aromatic hydrocarbon, a divalent group of an aromatic heterocycle, and a divalent group of a condensed polycyclic aromatic compound, Ar¹ represents an unsubstituted phenyl group, Ar² is selected from a group consisting of an aromatic hydrocarbon group, an aromatic heterocyclic group, and a condensed polycyclic aromatic group, R¹ to R⁹ are identical to or different from each other and are selected from a group consisting of a hydrogen atom, a deuterium atom, a fluorine atom, a chlorine atom, a cyano group, a trifluoromethyl group, a C1-C6 alkyl group, an aromatic hydrocarbon group, an aromatic heterocyclic group, and a condensed polycyclic aromatic group, W, X, Y, and Z each represent a carbon atom or a nitrogen atom, only one of W, X, Y, and Z is a nitrogen atom unbound with the hydrogen atoms or substituents of R¹ to R⁴.

5. An organic electroluminescent display device comprising:
a luminescent layer containing a material and a host material, the material including a luminescent dopant part and an assist dopant part.

6. The organic electroluminescent display device according to claim 5, wherein
the luminescent dopant part has an energy of 2.6 eV or higher to 3.0 eV or lower in an excited singlet state S₁ level,
the assist dopant part has an energy of 2.4 eV or higher to 3.0 eV or lower in the excited singlet state S₁ level, and
an energy gap ΔE_{ST} between the excited singlet state S₁ and an excited triplet state T₁ is 0 eV or larger to 2.0 eV or smaller.

7. The organic electroluminescent display device according to claim 6, wherein
the host material has an energy of 2.8 eV or higher in the excited triplet state T₁ level and an energy in the excited singlet state S₁ level that is higher than that of the assist dopant part in the excited singlet state S₁ by +0.4 eV or more.

8. The organic electroluminescent display device according to claim 5, wherein
the material including the luminescent dopant part and the assist dopant part is selected from a group consisting of compounds represented by formulae (1) to (6): 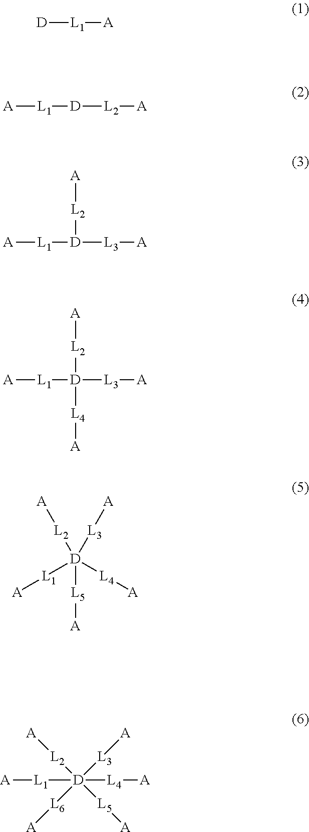
wherein D represents the luminescent dopant part; A represents the assist dopant part; and L is selected from a group consisting of a single bond, a nitrogen atom, an oxygen atom, a sulfur atom, a substituted or unsubstituted divalent hydrocarbon group, a substituted or unsubstituted divalent hydrocarbon group including one or more double bonds, a substituted or unsubstituted divalent hydrocarbon group including one or more triple bonds, and a substituted or unsubstituted divalent hydrocarbon group including one or more double bonds and triple bonds.

9. The organic electroluminescent display device according to claim 5, wherein
the assist dopant part is selected from a group consisting of substituents represented by formulae (7) to (24): 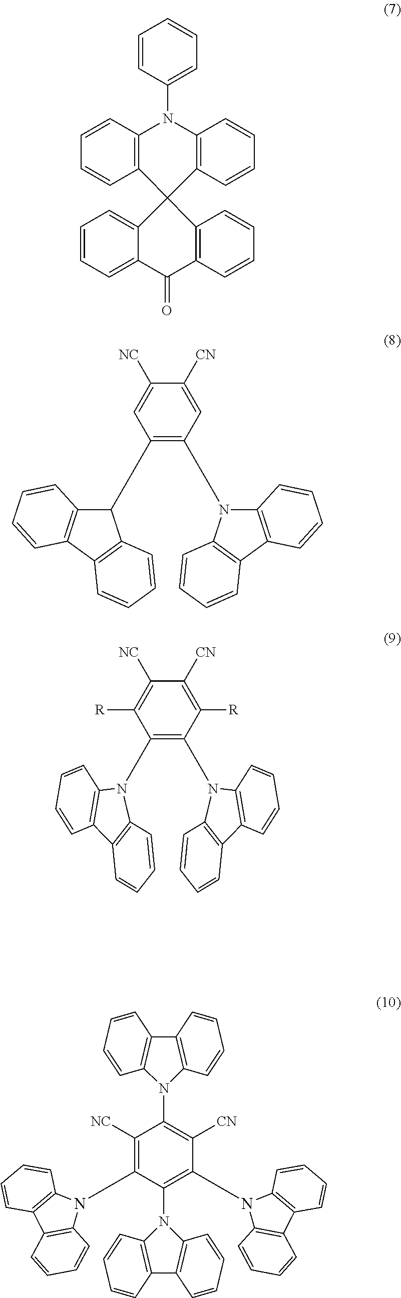 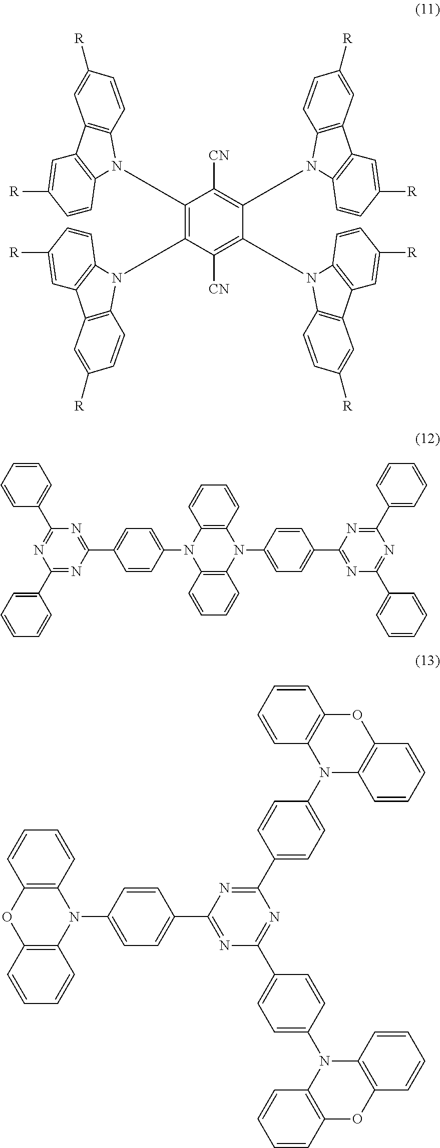 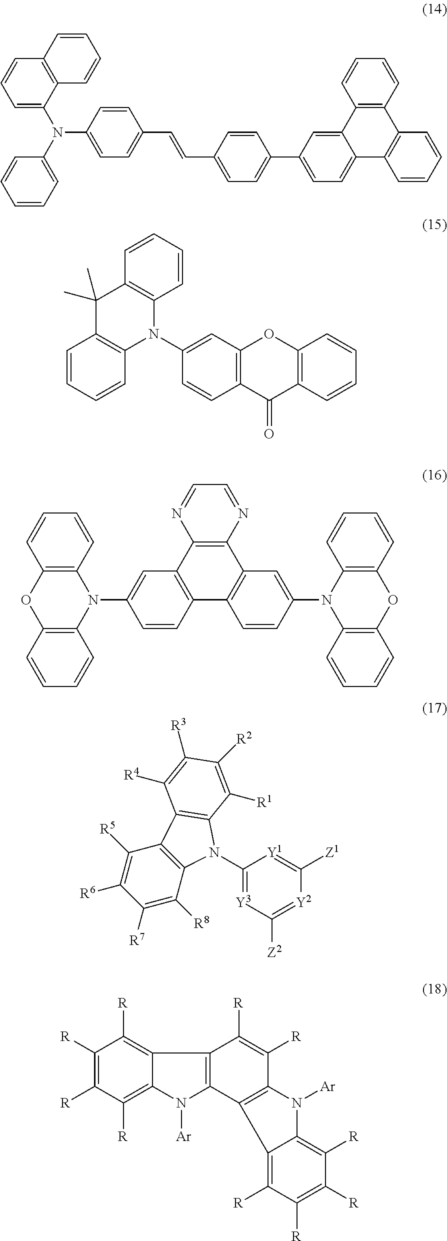 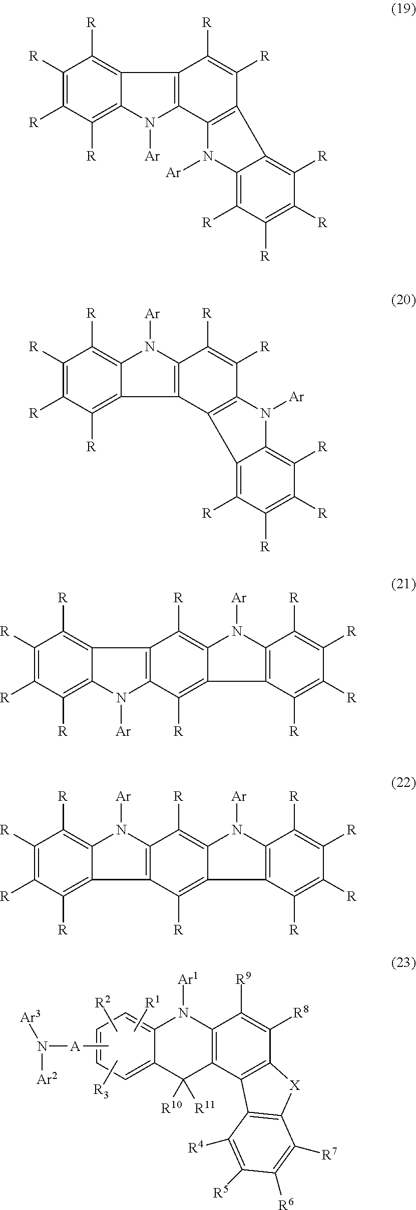 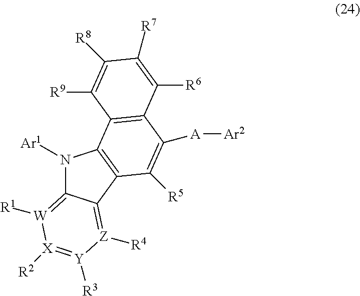
wherein, in formula (9), R represents a hydrogen atom or a carbazolyl group;
in formula (11), R represents a hydrogen atom, a methyl group, or a phenyl group;
in formula (17), R is selected from a group consisting of a hydrogen atom, a methyl group, and a phenyl group, Y² and Y³ represent nitrogen atoms and Y¹ represents a methine group or all of Y¹, Y², and Y³ represent nitrogen atoms, Z¹ and Z² independently represent a hydrogen atom or a substituent, Z² is selected from a group consisting of a hydrogen atom, a substituted or unsubstituted alkyl group, and a substituted or unsubstituted aryl group when Y² and Y³ are nitrogen atoms and Y¹ is a methine group, R¹ to R⁸ independently represent a hydrogen atom or a substituent, at least one of R¹ to R⁸ represents a substituted or unsubstituted diarylamino group or a substituted or unsubstituted carbazolyl group, and at least one of R¹ to R⁹ represents a substituted or unsubstituted diarylamino group or a substituted or unsubstituted 9-carbazolyl group and includes at least two carbazole structures when all of Y¹, Y², and Y³ are nitrogen atoms;
in formulae (18) to (22), each Ar independently represents an aromatic hydrocarbon group or an aromatic heterocyclic group and each R independently represents hydrogen or a monovalent substituent and includes a structure forming or unforming a ring by combining adjacent substituents;
in formula (23), X represents an oxygen atom or a sulfur atom, R¹ to R⁹ are selected from a group consisting of a hydrogen atom, a deuterium atom, a fluorine atom, a chlorine atom, a cyano group, a nitro group, a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, and an aryloxy group and have structures forming or unforming a ring by binding with each other via a single bond, a methylene group, an oxygen atom, or a sulfur atom, R¹⁰ and R¹¹ are selected from a group consisting of a C1-C6 alkyl group, a C5-C10 cycloalkyl group, a C2-C6 alkenyl group, a C1-C6 alkyloxy group, a C5-C10 cycloalkyloxy group, an aromatic hydrocarbon group, an aromatic heterocyclic group, a condensed polycyclic aromatic group, and an aryloxy group and have structures forming or unforming a ring by binding with each other via a single bond, a methylene group, an oxygen atom, or a sulfur atom, Ar¹, Ar², and Ar³ are selected from a group consisting of an aromatic hydrocarbon group, an aromatic heterocyclic group, and a condensed polycyclic aromatic group, Ar² and Ar³ have structures forming or unforming a ring by binding with each other via a single bond, a methylene group, an oxygen atom, or a sulfur atom, A represents either a divalent group of an aromatic hydrocarbon, an aromatic heterocycle, or a condensed polycyclic aromatic compound or a single bond, and in a case where A is a divalent group of an aromatic hydrocarbon, an aromatic heterocycle, or a condensed polycyclic aromatic compound, A and Ar² have structures forming or unforming a ring by binding with each other via a single bond, a methylene group, an oxygen atom, or a sulfur atom; and
in formula (24), A is selected from a group consisting of a single bond, a divalent group of an aromatic hydrocarbon, a divalent group of an aromatic heterocycle, and a divalent group of a condensed polycyclic aromatic compound, Ar¹ represents an unsubstituted phenyl group, Ar² is selected from a group consisting of an aromatic hydrocarbon group, an aromatic heterocyclic group, and a condensed polycyclic aromatic group, R¹ to R⁹ are identical to or different from each other and are selected from a group consisting of a hydrogen atom, a deuterium atom, a fluorine atom, a chlorine atom, a cyano group, a trifluoromethyl group, a C1-C6 alkyl group, an aromatic hydrocarbon group, an aromatic heterocyclic group, and a condensed polycyclic aromatic group, W, X, Y, and Z each represent a carbon atom or a nitrogen atom, only one of W, X, Y, and Z is a nitrogen atom unbound with the hydrogen atoms or substituents of R¹ to R⁴.
